(19) United States
(12) Patent Application Publication
(10) Pub. No.: US 2021/0062041 A1
(43) Pub. Date: Mar. 4, 2021

(54) POLISHING LIQUID, POLISHING LIQUID SET, AND POLISHING METHOD

(71) Applicant: HITACHI CHEMICAL COMPANY, LTD., Tokyo (JP)

(72) Inventors: Keita ARAKAWA, Chiyoda-ku, Tokyo (JP); Daisuke IIKURA, Chiyoda-ku, Tokyo (JP)

(21) Appl. No.: 16/962,375

(22) PCT Filed: Jan. 18, 2018
(86) PCT No.: PCT/JP2018/001404

§ 371 Date: Jul. 15, 2020

(51) Int. Cl. C09G 1/02; B24B 37/04; H01L 21/3105

(52) U.S. Cl. CPC C09G 1/02; H01L 21/31053; B24B 37/042

(57) ABSTRACT

A polishing liquid containing abrasive grains, a quaternary phosphonium cation, and a liquid medium, in which the abrasive grains contain at least one selected from the group consisting of a metal hydroxide and cerium oxide, and the quaternary phosphonium cation has a hydrocarbon group having two or more carbon atoms which is bonded to a phosphorus atom.

### TECHNICAL FIELD

The present invention relates to a polishing liquid, a polishing liquid set, and a polishing method.

### BACKGROUND ART

In the manufacturing steps for semiconductor elements of recent years, the importance of processing technologies for density increase and micronization is increasing more and more. CMP (Chemical mechanical polishing) technology, which is one of the processing technologies, has become an essential technology for the formation of a shallow trench isolation (hereinafter, referred to as “STI”), flattening of a pre-metal insulating material or an interlayer insulating material, formation of a plug or an embedded metal wiring, or the like, in the manufacturing steps for semiconductor elements. As a CMP polishing liquid, silica-based CMP polishing liquids containing silica (silicon oxide) particles such as fumed silica and colloidal silica have been known. Furthermore, a cerium oxide-based CMP polishing liquids containing cerium oxide (ceria) particles have been known (see, for example, Patent Literatures 1 and 2 below).

In the manufacturing steps for semiconductor elements of recent years, it is required to achieve further micronization of wiring, and polishing scratches generated during polishing are becoming problematic. That is, when polishing is performed using a conventional cerium oxide-based polishing liquid, even if minute polishing scratches are generated, there has been no problem as long as the sizes of these polishing scratches are smaller than conventional wiring widths; however, in a case where it is directed to achieve further micronization of the wiring, even minute polishing scratches become problematic.

With regard to this problem, an investigation has been conducted on polishing liquids that use particles of a hydroxide of a tetravalent metal element (see, for example, Patent Literature 3 below). Furthermore, methods for producing particles of a hydroxide of a tetravalent metal element have also been investigated (see, for example, Patent Literature 4 below). These technologies are directed to reduce polishing scratches caused by particles, by making the mechanical action as small as possible while utilizing the chemical action of particles of a hydroxide of a tetravalent metal element (see, for example, Patent Literature 5 below).

### CITATION LIST

### Patent Literature

Patent Literature 1: Japanese Unexamined Patent Publication No. H10-106994

Patent Literature 2: Japanese Unexamined Patent Publication No. H08-022970

Patent Literature 3: International Publication WO 2002/067309

Patent Literature 4: Japanese Unexamined Patent Publication No. 2006-249129

Patent Literature 5: Japanese Unexamined Patent Publication No. 2002-241739

Patent Literature 6: International Publication WO 2012/070544

### SUMMARY OF INVENTION

### Technical Problem

In a CMP step, as one of means for stopping polishing at a predetermined position, a stopper (a polishing stopping member; a member containing a stopper material) is used in some cases. In an example of the CMP step using the stopper, a base substrate, which has a substrate having a concavo-convex pattern, a stopper disposed on the convex portion of the substrate, and an insulating material disposed on the substrate and the stopper so as to embed the concave portion, is polished so as to remove an unnecessary portion of the insulating material. The reason for this is that the amount of the insulating material polished (the amount of the insulating material removed) is difficult to be controlled, and thus the insulating material is polished until the stopper is exposed, thereby controlling the degree of polishing. In such polishing, it is necessary to suppress the polishing rate for the stopper material, and in recent years, since the case of using polysilicon as a stopper material is increasing, it is necessary to suppress the polishing rate for polysilicon.

The present invention is conceived in view of such circumstances, and an object thereof is to provide a polishing liquid in which a polishing rate for polysilicon can be suppressed. Another object of the present invention is to provide a polishing liquid set for obtaining the above-described polishing liquid. Still another object of the present invention is to provide a polishing method which uses the above-described polishing liquid or the above-described polishing liquid set.

### Solution to Problem

A first embodiment of a polishing liquid of the present invention contains abrasive grains, a quaternary phosphonium cation, and a liquid medium, in which the abrasive grains contain a metal hydroxide, and the quaternary phosphonium cation has a hydrocarbon group having two or more carbon atoms which is bonded to a phosphorus atom. A second embodiment of a polishing liquid of the present invention contains abrasive grains, a quaternary phosphonium cation, and a liquid medium, in which the abrasive grains contain cerium oxide, and the quaternary phosphonium cation has a hydrocarbon group having two or more carbon atoms which is bonded to a phosphorus atom.

According to the polishing liquid of the present invention, the polishing rate for polysilicon can be suppressed. Furthermore, according to the polishing liquid of the present invention, the polishing rate for polysilicon can be suppressed while securing the polishing rate for a material to be removed (a material to be actively polished at a high polishing rate and removed; for example, an insulating material), and the polishing selectivity of the material to be removed with respect to polysilicon (polishing rate ratio: polishing rate for material to be removed/polishing rate for polysilicon) can be enhanced. According to the polishing liquid of the present invention, the polishing selectivity of the insulating material (for example, silicon oxide) with respect to polysilicon (polishing rate ratio: polishing rate for insulating material/polishing rate for polysilicon) can be enhanced. According to the present invention, polishing of a base substrate, which has a stopper containing polysilicon and a member containing an insulating material (for example, silicon oxide), can be stopped by the stopper.

The metal hydroxide in the first embodiment of the polishing liquid of the present invention preferably contains cerium hydroxide.

The hydrocarbon group may contain a butyl group, or may be a phenyl group.

The quaternary phosphonium cation in the polishing liquid of the present invention preferably contains a phosphonium cation represented by general formula (I) below.

### [Chemical Formula 1]

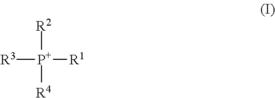

[In the formula, R¹, R², R³, and R⁴ each independently represent a hydrogen atom or a hydrocarbon group which may have a substituent, at least one of R¹, R², R³, and R⁴ is a hydrocarbon group having two or more carbon atoms which may have a substituent, and phosphorus atoms P in the formula may be bonded to each other through R¹, R², R³, or R⁴.]

At least one selected from the group consisting of R¹, R², R³, and R⁴ in general formula (I) may be a hydrocarbon group substituted with at least one selected from the group consisting of a carboxyl group, a hydroxyl group, an alkoxy group, a halogeno group, an ether group, an ester group, an aldehyde group, a carbonyl group, a nitro group, a silyl group, a cyano group, an amino group, an alkylamino group, a dialkylamino group, a homocyclic group, and a heterocyclic group.

Two or more of R¹, R², R³, and R⁴ in general formula (I) may be an unsubstituted hydrocarbon group.

R¹, R², R³, and R⁴ in general formula (I) may be an aryl group.

A content of a quaternary phosphonium salt having the quaternary phosphonium cation is preferably 0.001 to 1% by mass.

A pH of the polishing liquid of the present invention is preferably less than 8.0.

The polishing liquid of the present invention may be used for polishing a surface to be polished containing polysilicon.

A polishing liquid set of the present invention contains constituent components of the aforementioned polishing liquid stored while being divided into a plurality of liquids, a first liquid containing the abrasive grains, a second liquid containing the quaternary phosphonium cation. According to the polishing liquid set of the present invention, the same effect as that of the polishing liquid of the present invention can be obtained.

A polishing method of the present invention includes a step of polishing a surface to be polished by using the aforementioned polishing liquid or a polishing liquid obtained by mixing the first liquid and the second liquid of the aforementioned polishing liquid set. According to the polishing method of the present invention, the same effect as that of the polishing liquid of the present invention can be obtained.

In the polishing method of the present invention, the surface to be polished may contain polysilicon.

### Advantageous Effects of Invention

According to the present invention, the polishing rate for polysilicon can be suppressed. According to the present invention, polishing of a base substrate, which has a stopper containing polysilicon and a member containing an insulating material (for example, silicon oxide), can be stopped by the stopper.

The present invention can be used in a flattening step of a base substrate surface, that is a manufacturing technology of semiconductor elements. The present invention can be used in a flattening step of insulating materials (for example, STI insulating materials, pre-metal insulating materials, and interlayer insulating materials).

According to the present invention, it is possible to provide a use of a polishing liquid or a polishing liquid set to a polishing step of selectively polishing an insulating material with respect to polysilicon. According to the present invention, it is possible to provide a use of a polishing liquid or a polishing liquid set to a polishing step of stopping polishing of a base substrate, which has a stopper containing polysilicon and a member containing an insulating material, by the stopper.

### BRIEF DESCRIPTION OF DRAWINGS

FIG. 1 is a schematic cross-sectional view illustrating a polishing step when an STI structure of a semiconductor is formed.

### DESCRIPTION OF EMBODIMENTS

Hereinafter, an embodiment of the present invention will be described.

In the present specification, a numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical value range may be replaced with the value shown in the examples. “A or B” may include either one of A and B, and may also include both of A and B. Materials listed as examples in the present specification can be used singly or in combinations of two or more, unless otherwise specifically indicated. In the present specification, when a plurality of substances corresponding to each component exist in the composition, the content of each component in the composition means the total amount of the plurality of substances that exist in the composition, unless otherwise specified.

<Polishing Liquid and Polishing Liquid Set>

A polishing liquid of the present embodiment is a composition which is in contact with a surface to be polished during polishing, and is, for example, a CMP polishing liquid. The polishing liquid of the present embodiment contains abrasive grains, a quaternary phosphonium cation, and a liquid medium, in which the abrasive grains contain at least one selected from the group consisting of a metal hydroxide (a hydroxide of a metal element) and cerium oxide, and the quaternary phosphonium cation has a hydrocarbon group having two or more carbon atoms which is bonded to a phosphorus atom.

According to the present embodiment, the polishing rate for a stopper material such as polysilicon, amorphous silicon, or crystalline silicon can be suppressed. The reasons why such an effect is exhibited are not necessarily clearly known; however, the present inventors speculate the reasons to be as follows.

That is, since a phosphorus atom of the quaternary phosphonium cation having the hydrocarbon group having two or more carbon atoms which is bonded to a phosphorus atom (hereinafter, referred to as “specific quaternary phosphonium cation” in some cases) is positively charged, the specific quaternary phosphonium cation is adsorbed to the surface of the stopper material (polysilicon, amorphous silicon, crystalline silicon, or the like) negatively charged by electrostatic attractive force, and thus a protection layer is formed on the surface of the stopper material.

Then, in the case of using abrasive grains containing a metal hydroxide, a material to be removed (for example, an insulating material such as silicon oxide) is polished by chemical action (see, for example, Patent Literature 5 described above). Furthermore, in the case of using abrasive grains containing cerium oxide, a material to be removed (for example, an insulating material such as silicon oxide) is polished by chemical action such as oxidation action of the cerium oxide.

In a case where the stopper material is polished by concurrently using the abrasive grains utilizing such chemical action and the specific quaternary phosphonium cation, the chemical action between the abrasive grains and the material to be removed is inhibited by the aforementioned protection layer formed on the surface of the stopper material. According to this, the polishing rate for the stopper material is suppressed.

Although a nitrogen atom of a quaternary ammonium cation is positively charged, the polishing rate for the stopper material cannot be suppressed. The reasons for this are not necessarily clearly known; however, the present inventors speculate the reasons to be as follows. That is, generally, if the valences of ions are the same, as the ion radius increases, the ion has small hydration entropy and thus shows the hydrophobic property. Therefore, when comparing a phosphorus atom and a nitrogen atom, since the ion radius of the phosphorus atom is larger than the ion radius of the nitrogen atom, the specific quaternary phosphonium cation has more hydrophobic property than the quaternary ammonium cation (for example, in Journal of the Chemical Society of Japan, 1980, (7), p. 1148 to 1153, solubility parameters (a larger value represents higher hydrophobicity) of (C₄H₉)₄NBr and (C₄H₉)₄PBr having the same functional group are shown, and it is shown that the solubility parameter of (C₄H₉)₄PBr is larger than that of (C4H9)4NBr). Further, generally, the surface of the stopper material has a hydrophobic surface state. Therefore, in the case of using the specific quaternary phosphonium cation, since both the specific quaternary phosphonium cation and the stopper material sufficiently have hydrophobic properties, the specific quaternary phosphonium cation is easily adsorbed to the surface of the stopper material. Therefore, a protection layer is formed on the surface of the stopper material, and thus the suppression effect of the stopper material is obtainable. On the other hand, in the case of using the quaternary ammonium cation, since the hydrophobic property of the quaternary ammonium cation is weaker than that of the specific quaternary phosphonium cation, a protection layer is difficult to be formed on the surface of the stopper material. Therefore, the suppression effect of the stopper material is not obtainable.

Furthermore, in the specific quaternary phosphonium cation, the hydrocarbon group having two or more carbon atoms which is bonded to a phosphorus atom has higher hydrophobicity than a hydrocarbon group having less than two carbon atoms. In this case, since the hydrophobic property is sufficiently exhibited, the specific quaternary phosphonium cation is easily adsorbed to the surface of the stopper material. On the other hand, in a case where the quaternary phosphonium cation does not have a hydrocarbon group having two or more carbon atoms which is bonded to a phosphorus atom and has only a hydrocarbon group having less than two carbon atoms which is bonded to a phosphorus atom, the hydrophobicity of the hydrocarbon group is low. In this case, since the hydrophobic property is not sufficiently exhibited, a protection layer is difficult to be formed on the surface of the stopper material, and thus the suppression effect of the stopper material is not obtainable.

(Abrasive Grains)

The polishing liquid of the present embodiment contains abrasive grains. The abrasive grains contain at least one selected from the group consisting of a metal hydroxide and cerium oxide. That is, the abrasive grains may be an embodiment containing a metal hydroxide, and may be an embodiment containing cerium oxide.

The metal hydroxide preferably contains a hydroxide of at least one selected from the group consisting of a rare earth element and zirconium, from the viewpoints of suppressing the occurrence of polishing scratches in the polished surface while further improving the polishing selectivity of the material to be removed (for example, an insulating material) with respect to the stopper material (for example, polysilicon). The metal hydroxide preferably contains a hydroxide of a rare earth element, from the viewpoint of further improving the polishing rate for the material to be removed (for example, an insulating material). Examples of the rare earth element include lanthanoids such as cerium, praseodymium, and terbium. The metal hydroxide preferably contains cerium hydroxide, from the viewpoints of easy availability and further excelling in the polishing rate for the material to be removed (for example, an insulating material). A hydroxide of a rare earth element and a hydroxide of zirconium may be used in combination, and two or more kinds from hydroxides of rare earth elements can also be selected and used.

As the metal hydroxide, a hydroxide of a tetravalent metal element can be used. The “hydroxide of a tetravalent metal element” is a compound containing a tetravalent metal ion (M⁴⁺) and at least one hydroxide ion (OH⁻). The hydroxide of a tetravalent metal element may also contain an anion other than hydroxide ion (for example, nitrate ion NO^{3 -} and sulfate ion SO₄²⁻). For example, the hydroxide of a tetravalent metal element preferably contains an anion which is bonded to a tetravalent metal element (excluding hydroxide ion; for example, nitrate ion NO^{3 -} and sulfate ion SO₄²⁻) and more preferably contains nitrate ion which is bonded to a tetravalent metal element, from the viewpoint of further improving the polishing rate for the material to be removed (for example, an insulating material such as silicon oxide).

The hydroxide of a metal element (for example, a hydroxide of a tetravalent metal element) can be produced by reacting a salt (metal salt) of a metal element (for example, a tetravalent metal element) with an alkali source (base). It is preferable that the hydroxide of a metal element is produced by mixing a salt of a metal element with an alkali solution (for example, an aqueous alkali solution). Thereby, particles having a very fine particle size can be obtained, and a polishing liquid having a further excellent effect of reducing polishing scratches can be obtained. Such a technique is disclosed in, for example, Patent Literature 6 described above. The hydroxide of a metal element can be obtained by mixing a metal salt solution containing a salt of a metal element (for example, an aqueous solution of a metal salt) with an alkali solution. Regarding the salt of a metal element, conventionally known salts can be used without any particular limitations, and examples thereof include M(NO₃)₄, M(SO₄)₂, M(NH₄)₂(NO₃)₆, M(NH₄)₄(SO₄)₄ (wherein M represents a rare earth element), and Zr(SO₄)₂4H₂O. Cerium (Ce) which is chemically active is preferable for M.

The cerium oxide can be obtained by oxidizing cerium salts such as carbonates, nitrates, sulfates, and oxalates. Examples of the oxidation method include a firing method in which the cerium salt is fired at 600° C. to 900° C. and a chemical oxidation method in which the cerium salt is oxidized using an oxidizing agent such as hydrogen peroxide.

The cerium oxide can also be obtained by thermally decomposing a cerium compound obtained using, as a starting material, cerium salts such as carbonates, nitrates, sulfates, and oxalates. Examples of the method using the thermal decomposition include a precipitation method, a hydrolysis method, and a sol-gel method.

The cerium oxide can be obtained by any method of a solid phase method, a liquid phase method, and a gas phase method. For example, as the cerium oxide, an oxide (for example, colloidal ceria) obtained by a liquid phase method can be used. Examples of the solid phase method include a firing method, a thermal decomposition method, and a solid-phase reaction method. Examples of the liquid phase method include a precipitation method, a solvent evaporation method, and a liquid-phase reaction method. Examples of the gas phase method include a gas-phase reaction method and an evaporation-condensation method.

The polishing liquid of the present embodiment may further contain other kinds of abrasive grains. Specifically, for example, abrasive grains containing silica, alumina, zirconia, organic resin particles, or the like are mentioned.

The content of the abrasive grains is preferably in the following range on the basis of the total mass of the polishing liquid. The lower limit of the content of the abrasive grains is preferably 0.005% by mass or more, more preferably 0.01% by mass or more, even more preferably 0.02% by mass or more, particularly preferably 0.03% by mass or more, extremely preferably 0.04% by mass or more, and extremely preferably 0.05% by mass or more, from the viewpoint of easily obtaining a desired polishing rate for the material to be removed (for example, an insulating material). The upper limit of the content of the abrasive grains is preferably 20% by mass or less, more preferably 10% by mass or less, even more preferably 5% by mass or less, particularly preferably 3% by mass or less, extremely preferably 1% by mass or less, highly preferably 0.5% by mass or less, and still even more preferably 0.3% by mass or less, from the viewpoints that the aggregation of the abrasive grains are easily avoided, and the abrasive grains effectively act on the surface to be polished such that polishing smoothly proceeds. From these viewpoints, the content of the abrasive grains is preferably 0.005 to 20% by mass.

In a case where the abrasive grains contain a metal hydroxide (for example, a hydroxide of a tetravalent metal element), the content of the abrasive grains is preferably in the following range on the basis of the total mass of the polishing liquid. The lower limit of the content of the abrasive grains is preferably 0.005% by mass or more, more preferably 0.01% by mass or more, even more preferably 0.02% by mass or more, particularly preferably 0.03% by mass or more, extremely preferably 0.04% by mass or more, and highly preferably 0.05% by mass or more, from the viewpoint of easily exhibiting the function of the metal hydroxide sufficiently. The upper limit of the content of the abrasive grains is preferably 20% by mass or less, more preferably 10% by mass or less, even more preferably 5% by mass or less, particularly preferably 3% by mass or less, extremely preferably 1% by mass or less, highly preferably 0.5% by mass or less, still even more preferably 0.3% by mass or less, and more preferably 0.1% by mass or less, from the viewpoints of easily avoiding the aggregation of the abrasive grains, and easily obtaining favorable chemical interaction with a surface to be polished to easily utilize the properties of the abrasive grains effectively. From these viewpoints, the content of the abrasive grains is preferably 0.005 to 20% by mass.

In a case where the abrasive grains contain cerium oxide, the content of the abrasive grains is preferably in the following range on the basis of the total mass of the polishing liquid. The lower limit of the content of the abrasive grains is preferably 0.005% by mass or more, more preferably 0.01% by mass or more, even more preferably 0.02% by mass or more, particularly preferably 0.03% by mass or more, extremely preferably 0.04% by mass or more, highly preferably 0.05% by mass or more, still even more preferably 0.1% by mass or more, and more preferably 0.2% by mass or more, from the viewpoint of easily obtaining a desired polishing rate for the material to be removed (for example, an insulating material). The upper limit of the content of the abrasive grains is preferably 20% by mass or less, more preferably 10% by mass or less, even more preferably 5% by mass or less, particularly preferably 3% by mass or less, extremely preferably 1% by mass or less, highly preferably 0.5% by mass or less, and still even more preferably 0.3% by mass or less, from the viewpoints of easily avoiding the aggregation of the abrasive grains, and easily obtaining favorable chemical interaction with a surface to be polished to easily utilize the properties of the abrasive grains effectively. From these viewpoints, the content of the abrasive grains is preferably 0.005 to 20% by mass.

In a case where the abrasive grains contain a metal hydroxide (for example, a hydroxide of a tetravalent metal element), the content of the abrasive grains is preferably in the following range on the basis of the whole abrasive grains (the whole abrasive grains contained in the polishing liquid). The lower limit of the content of the abrasive grains containing the metal hydroxide is preferably 50% by mass or more, more preferably 70% by mass or more, even more preferably 90% by mass or more, particularly preferably 95% by mass or more, and extremely preferably 97% by mass or more, from the viewpoint of further suppressing the polishing rate for the stopper material (for example, polysilicon). The upper limit of the content of the abrasive grains containing the metal hydroxide may be 100% by mass.

In a case where the abrasive grains contain cerium oxide, the content of the abrasive grains is preferably in the following range on the basis of the whole abrasive grains (the whole abrasive grains contained in the polishing liquid). The lower limit of the content of the abrasive grains containing the cerium oxide is preferably 50% by mass or more, more preferably 70% by mass or more, even more preferably 90% by mass or more, particularly preferably 95% by mass or more, and extremely preferably 97% by mass or more, from the viewpoint of further suppressing the polishing rate for the stopper material (for example, polysilicon). The upper limit of the content of the abrasive grains containing the cerium oxide may be 100% by mass.

In a case where the average particle size (average secondary particle size) of the abrasive grains is small to some extent, the polishing rate for the material to be removed (for example, an insulating material) can be further improved by increasing the specific surface area of the abrasive grains that are in contact with the surface to be polished, and the mechanical action is suppressed so that polishing scratches can be further reduced. Therefore, the upper limit of the average particle size of the abrasive grains containing the metal hydroxide is preferably 300 nm or less, more preferably 200 nm or less, even more preferably 150 nm or less, particularly preferably 100 nm or less, extremely preferably 80 nm or less, highly preferably 60 nm or less, still even more preferably 40 nm or less, more preferably 20 nm or less, and even more especially preferably 10 nm or less, from the viewpoints of obtaining a further excellent polishing rate for the material to be removed (for example, an insulating material) and further reducing polishing scratches. The lower limit of the average particle size of the abrasive grains containing the metal hydroxide is preferably 1 nm or more, more preferably 2 nm or more, even more preferably 3 nm or more, and particularly preferably 5 nm or more, from the viewpoints of obtaining a further excellent polishing rate for the material to be removed (for example, an insulating material) and further reducing polishing scratches. From these viewpoints, the average particle size of the abrasive grains containing the metal hydroxide is preferably 1 to 300 nm.

In a case where the average particle size (average secondary particle size) of the abrasive grains is small to some extent, the polishing rate for the material to be removed (for example, an insulating material) can be further improved by increasing the specific surface area of the abrasive grains that are in contact with the surface to be polished, and the mechanical action is suppressed so that polishing scratches can be further reduced. Therefore, the upper limit of the average particle size of the abrasive grains containing the cerium oxide is preferably 300 nm or less, more preferably 250 nm or less, even more preferably 200 nm or less, and particularly preferably 180 nm or less, from the viewpoints of obtaining a further excellent polishing rate for the material to be removed (for example, an insulating material) and further reducing polishing scratches. The lower limit of the average particle size of the abrasive grains containing the cerium oxide is preferably 1 nm or more, more preferably 2 nm or more, even more preferably 10 nm or more, particularly preferably 50 nm or more, extremely preferably 100 nm or more, and highly preferably 150 nm or more, from the viewpoints of obtaining a further excellent polishing rate for the material to be removed (for example, an insulating material) and further reducing polishing scratches. From these viewpoints, the average particle size of the abrasive grains containing the cerium oxide is preferably 1 to 300 nm.

The average particle size of the abrasive grains can be measured by a photon correlation method, a laser diffraction scattering method, or the like. For example, the average particle size of the abrasive grains containing the metal hydroxide can be measured by apparatus name: N5 manufactured by Beckman Coulter, Inc. or the like. The average particle size of the abrasive grains containing the cerium oxide can be measured by a microtrack particle size distribution meter manufactured by NIKKISO CO., LTD. (for example, apparatus name: MT-3000II), or the like.

In measurement using N5, for example, first, an aqueous dispersion liquid having the content of the abrasive grains adjusted to 1.0% by mass is prepared, about 1 mL (L represents “liter”; the same applies hereinafter) of this aqueous dispersion liquid is introduced into a 1-cm square cell, and the cell is placed in the apparatus. Then, a refractive index of a dispersing medium is set to 1.333 and also a viscosity of a dispersing medium is set to 0.887 mPa·s, and a value obtainable by performing measurement at 25° C. can be used as the average particle size of the abrasive grains.

In measurement using MT-3000II, for example, the average particle size (MV), which is obtained by performing measurement after water (refractive index: 1.33) as a solvent was circulated, the aqueous dispersion liquid containing abrasive grains was added to the solvent until the dv value (diffraction light amount; an indication of measurement concentration in the microtrack) of the sample concentration was in a range of 0.0010 to 0.0011, can be employed as the average particle size of the abrasive grains.

In a case where the abrasive grains contain a hydroxide of a tetravalent metal element, it is preferable to satisfy the following light transmittance or absorbance.

The polishing liquid of the present embodiment preferably has high transparency for visible light (visually transparent or nearly transparent). Specifically, the abrasive grains contained in the polishing liquid of the present embodiment preferably produce light transmittance of 50%/cm or higher for light having a wavelength of 500 nm in an aqueous dispersion liquid having the content of the abrasive grains adjusted to 1.0% by mass. Thereby, a decrease in the polishing rate for the material to be removed (for example, an insulating material) due to the addition of an additive can be further suppressed, and therefore, it becomes easy to obtain other characteristics while maintaining the polishing rate. From the same viewpoint, the lower limit of the light transmittance is more preferably 60%/cm or higher, even more preferably 70%/cm or higher, particularly preferably 80%/cm or higher, extremely preferably 90%/cm or higher, and highly preferably 92%/cm or higher. The upper limit of the light transmittance is 100%/cm.

The reason why the decrease in the polishing rate for the material to be removed (for example, an insulating material) can be suppressed by adjusting the light transmittance of the abrasive grains in this manner is not understood in detail, but it is considered that the action of the abrasive grains containing a hydroxide of a tetravalent metal element (for example, cerium), as abrasive grains, is more dominantly depend on the chemical action than on the mechanical action. Therefore, it is considered that the number of abrasive grains contributes to the polishing rate rather than the size of the abrasive grains.

In a case where the light transmittance of an aqueous dispersion liquid having the content of the abrasive grains adjusted to 1.0% by mass is low, it is considered that the abrasive grains present in the aqueous dispersion liquid contain a relatively larger portion of particles having a large particle size (hereinafter, referred to as “coarse particles”). When an additive is added to the polishing liquid containing such abrasive grains, coarse particles serve as nuclei, and other particles aggregate around thereon. As a result, it is considered that, since the number of abrasive grains acting on the surface to be polished per unit area (effective number of abrasive grains) is reduced, and the specific surface area of the abrasive grains that are in contact with the surface to be polished is reduced, the polishing rate is decreased.

On the other hand, in a case where the light transmittance in an aqueous dispersion liquid having the content of the abrasive grains adjusted to 1.0% by mass is high, it is considered that the abrasive grains present in the aqueous dispersion liquid are in a state in which there are few “coarse particles”. In a case where the abundance of coarse particles is small like this, even if an additive is added to the polishing liquid, since there are few coarse particles that become the nuclei of aggregation, aggregation between abrasive grains is suppressed, or the size of the aggregated particles is relatively small. As a result, it is considered that, since the number of abrasive grains acting on the surface to be polished per unit area (effective number of abrasive grains) is maintained, and the specific surface area of the abrasive grains that are in contact with the surface to be polished is maintained, the polishing rate is difficult to decrease.

It can be seen from the studies in the past that, even for polishing liquids having the same particle size of the abrasive grains measured with a general particle size analyzer, there may be a polishing liquid that is visually transparent (the light transmittance is high) and a polishing liquid that is visually cloudy (the light transmittance is low). According to this, it is considered that coarse particles that can cause such action as described above contribute to a decrease in the polishing rate even with a very small amount that is undetectable with a general particle size analyzer.

The above-described light transmittance is a transmittance for light having a wavelength of 500 nm. The above-described light transmittance is measured by a spectrophotometer, and specifically, is measured by a spectrophotometer U3310 (apparatus name) manufactured by Hitachi, Ltd., for example.

As a more specific measurement method, an aqueous dispersion liquid having the content of the abrasive grains adjusted to 1.0% by mass is prepared as a measurement sample. About 4 mL of this measurement sample is introduced into a 1 cm×1 cm cell, the cell is placed in the apparatus, and measurement is performed.

When the abrasive grains containing the hydroxide of a tetravalent metal element provide an absorbance of 1.00 or higher for light having a wavelength of 400 nm in an aqueous dispersion liquid having the content of the abrasive grains adjusted to 1.0% by mass, the polishing rate for the material to be removed (for example, an insulating material) can be further improved. The reasons for this are not necessarily clearly known; however, it is considered that, depending on the production conditions for the hydroxide of a tetravalent metal element, or the like, particles represented by composition formula: M(OH)ₐX_{b} (wherein a+b×c=4) composed of one tetravalent metal (M⁴⁺), one to three hydroxide ions (OH), and one to three anions (X^{c-}) are produced as a part of the abrasive grains (incidentally, such particles are also “abrasive grains containing a hydroxide of a tetravalent metal element”). It is considered that, in M(OH)ₐX_{b}, an electron-withdrawing anion (X^{c-}) acts so that the reactivity of hydroxide ion is enhanced, and the polishing rate is improved along with an increase in the abundance of M(OH)ₐX_{b}. Furthermore, it is considered that, since particles represented by composition formula: M(OH)ₐX_{b} absorbs light having a wavelength of 400 nm, the polishing rate is improved along with an increase in the abundance of M(OH)ₐX_{b} for increasing the absorbance for light having a wavelength of 400 nm.

It is considered that abrasive grains containing a hydroxide of a tetravalent metal element may contain not only particles represented by composition formula: M(OH)ₐX_{b} but also particles represented by composition formulas: M(OH)₄, MO₂, or the like. Examples of the anion (X^{c-}) include NO₃⁻ and SO₄²⁻.

Incidentally, whether the abrasive grains have composition formula: M(OH)ₐX_{b} can be confirmed by a method of thoroughly washing the abrasive grains with pure water and then detecting peaks corresponding to the anion (X^{C-}) by using FT-IR ATR method (Fourier Transform Infra Red Spectrometer Attenuated Total Reflection method). The presence of the anion (X^{C-}) can also be confirmed by XPS method (X-ray Photoelectron Spectroscopy). Furthermore, from X-ray absorption fine structure (XAFS) measurement, the existence of bonding between M and the anion (X^{C-}) can also be confirmed by performing EXAFS analysis.

Here, it has been confirmed that an absorption peak at a wavelength of 400 nm of M(OH)ₐX_{b} (for example, M(OH)₃X) is much smaller than the below-mentioned absorption peak at a wavelength of 290 nm. In this regard, in the case of using abrasive grains that provide an absorbance of 1.00 or higher for light having a wavelength of 400 nm in an aqueous dispersion liquid having a content of the abrasive grains of 1.0% by mass, which has a relatively large content of abrasive grains and whose absorbance is likely to be detected to be high, an effect of improving the polishing rate for the material to be removed (for example, an insulating material) is excellent.

The lower limit of the absorbance for light having a wavelength of 400 nm is preferably 1.00 or higher, more preferably 1.20 or higher, even more preferably 1.40 or higher, particularly preferably 1.50 or higher, extremely preferably 1.80 or higher, and highly preferably 2.00 or higher, from the viewpoint of obtaining a further excellent polishing rate for the material to be removed (for example, an insulating material).

When the abrasive grains containing the hydroxide of a tetravalent metal element provide an absorbance of 1.000 or higher for light having a wavelength of 290 nm in an aqueous dispersion liquid having the content of the abrasive grains adjusted to 0.0065% by mass, the polishing rate for the material to be removed (for example, an insulating material) can be further improved. The reasons for this are not necessarily clearly known; however, particles represented by composition formula: M(OH)ₐX_{b} (for example, M(OH)₃X), that are produced depending on the production conditions for the hydroxide of a tetravalent metal element, or the like, have an absorption peak near the wavelength of 290 nm according to calculations, and for example, particles composed of Ce⁴⁺(OH⁻)₃NO₃⁻ have an absorption peak at the wavelength of 290 nm. Therefore, it is considered that, as the abundance of M(OH)ₐX_{b} increases and thereby the absorbance for light having a wavelength of 290 nm increases, the polishing rate is improved.

Here, the absorbance for light having a wavelength of about 290 nm tends to be detected to a greater degree as the measuring limit is exceeded. In this regard, in the case of using abrasive grains that provide an absorbance of 1.000 or higher for light having a wavelength of 290 nm in an aqueous dispersion liquid having a content of the abrasive grains of 0.0065% by mass, which has a relatively small content of abrasive grains and whose absorbance is likely to be detected to be low, an effect of improving the polishing rate for the material to be removed (for example, an insulating material) is excellent.

The lower limit of the absorbance for light having a wavelength of 290 nm is preferably 1.000 or higher, more preferably 1.050 or higher, even more preferably 1.100 or higher, particularly preferably 1.150 or higher, and extremely preferably 1.190 or higher, from the viewpoint of polishing a material to be removed at a further excellent polishing rate. The upper limit of the absorbance for light having a wavelength of 290 nm is not particularly limited; however, for example, it is preferably 10.000 or lower.

In a case where the above-described abrasive grains, that provide an absorbance of 1.00 or higher for light having a wavelength of 400 nm, provide an absorbance of 1.000 or higher for light having a wavelength of 290 nm in an aqueous dispersion liquid having the content of the abrasive grains adjusted to 0.0065% by mass, a material to be removed can be polished at a further excellent polishing rate.

A hydroxide of a tetravalent metal element (for example, M(OH)aXb) tends not to absorb light having a wavelength of 450 nm or higher, particularly, a wavelength of 450 to 600 nm. Therefore, from the viewpoint of suppressing adverse influence on polishing as a result of containing impurities, and thereby polishing a material to be removed at a further excellent polishing rate, it is preferable that the abrasive grains provide an absorbance of 0.010 or lower for light having a wavelength of 450 to 600 nm in an aqueous dispersion liquid having the content of the abrasive grains adjusted to 0.0065% by mass (65 ppm). That is, it is preferable that the absorbance for entire light in the wavelength range of 450 to 600 nm in an aqueous dispersion liquid having the content of the abrasive grains adjusted to 0.0065% by mass does not exceed 0.010. The lower limit of the absorbance for light having a wavelength of 450 to 600 nm is preferably 0.

The absorbance in an aqueous dispersion liquid can be measured using, for example, a spectrophotometer (apparatus name: U3310) manufactured by Hitachi, Ltd. Specifically, for example, an aqueous dispersion liquid having the content of the abrasive grains adjusted to 1.0% by mass or 0.0065% by mass is prepared as a measurement sample. About 4 mL of this measurement sample is introduced into a 1-cm square cell, and the cell is placed in the apparatus. Next, measurement of the absorbance is performed in the wavelength range of 200 to 600 nm, and the absorbance is determined from a chart thus obtained.

The absorbance and light transmittance that are provided in the aqueous dispersion liquid by the abrasive grains can be measured by removing solid components other than the abrasive grains and liquid components other than water, subsequently preparing an aqueous dispersion liquid having a predetermined content of the abrasive grains, and performing measurement using this aqueous dispersion liquid. For removing the solid components or the liquid components, although varying depending on components contained in the polishing liquid, a centrifugation method such as centrifugation using a centrifuge that can apply a gravitational acceleration of several thousand G or less, or super-centrifugation using a super-centrifuge that can apply a gravitational acceleration of several ten thousand G or greater; a chromatographic method such as partition chromatography, adsorption chromatography, gel permeation chromatography, or ion exchange chromatography; a filtration method such as natural filtration, filtration under reduced pressure, pressure filtration, or ultrafiltration; a distillation method such as reduced pressure distillation or normal pressure distillation; or the like can be used, and these may also be used in combination as appropriate.

Examples of methods in a case where the polishing liquid contains a compound having a weight average molecular weight of several ten thousands or more (for example, 50000 or more) include a chromatographic method and a filtration method, and gel permeation chromatography or ultrafiltration is preferred. In the case of using a filtration method, the abrasive grains contained in the polishing liquid can be passed through a filter by setting appropriate conditions. Examples of methods in a case where the polishing liquid contains a compound having a weight average molecular weight of several ten thousands or less (for example, less than 50000) include a chromatographic method, a filtration method, and a distillation method, and gel permeation chromatography, ultrafiltration, or distillation under reduced pressure is preferred. Examples of methods in a case where abrasive grains other than the abrasive grains containing the hydroxide of a tetravalent metal element are contained in the polishing liquid include a filtration method and a centrifugation method, and more abrasive grains containing a hydroxide of a tetravalent metal element are contained in the filtrate in the case of filtration, and also contained in the liquid phase in the case of centrifugation.

As a method for separating the abrasive grains by the chromatography methods, for example, the abrasive grains and/or other components can be isolated by the following conditions.

Sample solution: 100 μL of polishing liquid

Detector: Manufactured by Hitachi, Ltd., UV-VIS detector, trade name: L-4200, wavelength: 400 nm

Integrator: Manufactured by Hitachi, Ltd., GPC integrator, trade name: D-2500

Pump: Manufactured by Hitachi, Ltd., trade name: L-7100

Column: Manufactured by Hitachi Chemical Company, Ltd., water-based packed column for HPLC, trade name: GL-W550S

Eluent: Deionized water

Measurement temperature: 23° C.

Flow rate: 1 mL/min (pressure: about 40 to 50 kgfcm² (3.9 to 4.9 MPa))

Measurement time: 60 min

Incidentally, a deaeration treatment of an eluent is preferably performed using a deaerator before performing chromatography. In a case where a deaerator cannot be used, an eluent is preferably deaeration-treated in advance with ultrasonic waves or the like.

Depending on the components contained in the polishing liquid, there is a possibility that the abrasive grains may not be isolated even under the above-described conditions; however, in that case, it is possible to separate the abrasive grains by optimizing the amount of the sample solution, the type of column, the type of eluent, the measurement temperature, the flow rate, and the like. Furthermore, there is a possibility that, by adjusting the pH of the polishing liquid to adjust the distillation time for the components contained in the polishing liquid, it is possible to separate these components from the abrasive grains. In a case where there are insoluble components in the polishing liquid, it is preferable to remove the insoluble components by filtration, centrifugation, and the like, according to necessity.

(Additive)

The polishing liquid of the present embodiment contains an additive. Herein, the term “additive” refers to a substance which the polishing liquid contains in addition to abrasive grains and a liquid medium. By using the additive, for example, it is possible to adjust the polishing characteristics such as a polishing rate and polishing selectivity; polishing liquid characteristics such as the dispersibility of the abrasive grains and storage stability; or the like.

[Quaternary Phosphonium Cation]

The polishing liquid of the present embodiment contains a quaternary phosphonium cation having a hydrocarbon group having two or more carbon atoms which is bonded to a phosphorus atom (specific quaternary phosphonium cation). The specific quaternary phosphonium cation in the polishing liquid of the present embodiment is dispersed in a liquid medium. The specific quaternary phosphonium cation can be used singly or in combination of two or more kinds thereof.

It is sufficient that the specific quaternary phosphonium cation has at least one hydrocarbon group having two or more carbon atoms which is bonded to a phosphorus atom, and in addition to the hydrocarbon group having two or more carbon atoms, a group different from the hydrocarbon group having two or more carbon atoms may be bonded to a phosphorus atom. Examples of the group different from the hydrocarbon group having two or more carbon atoms include a hydrocarbon group having one carbon atom (for example, a methyl group) and a group (for example, a halogeno group) different from the hydrocarbon group.

The lower limit of the number of carbon atoms of the hydrocarbon group which is bonded to a phosphorus atom may be 2 or more, 3 or more, 4 or more, 5 or more, or 6 or more, from the viewpoint of further suppressing the polishing rate for the stopper material (for example, polysilicon). The upper limit of the number of carbon atoms of the hydrocarbon group which is bonded to a phosphorus atom may be 30 or less, 20 or less, 16 or less, 14 or less, or 10 or less, from the viewpoint of easily suppressing the polishing rate for the stopper material (for example, polysilicon) since solubility in the liquid medium (for example, water) is excellent. From these viewpoints, the number of carbon atoms of the hydrocarbon group may be 2 to 30.

Examples of the hydrocarbon group include an alkyl group, an alkenyl group, an alkynyl group, and an aryl group. Examples of the alkenyl group include a vinyl group, an allyl group, and a cinnamyl group. Examples of the aryl group include a phenyl group, a benzyl group, a tolyl group, a xylyl group, a naphthyl group, and a naphthylmethyl group. The hydrocarbon group may contain a butyl group, or may contain a phenyl group.

The hydrocarbon group which is bonded to a phosphorus atom may have a substituent (is a substituted or unsubstituted hydrocarbon group). Examples of the substituent in the substituted hydrocarbon group include a carboxyl group, a hydroxyl group, an alkoxy group, a halogeno group, an ether group, an ester group, an aldehyde group, a carbonyl group, a nitro group, a silyl group, a cyano group, an amino group, an alkylamino group, a dialkylamino group, a homocyclic group, and a heterocyclic group. At least one selected from the group consisting of R¹, R², R³, and R⁴ in general formula (I) may be a hydrocarbon group substituted with at least one selected from the group consisting of a carboxyl group, a hydroxyl group, an alkoxy group, a halogeno group, an ether group, an ester group, an aldehyde group, a carbonyl group, a nitro group, a silyl group, a cyano group, an amino group, an alkylamino group, a dialkylamino group, a homocyclic group, and a heterocyclic group, from the viewpoints of easily obtaining the effect of suppressing the polishing rate for the stopper material (for example, polysilicon) while securing the polishing rate for the material to be removed. Examples of the alkoxy group include a methoxy group, an ethoxy group, and a propoxy group. Examples of the halogeno group include a fluoro group, a chloro group, a bromo group, and an iodine group. Examples of the homocyclic group include cycloalkylene groups such as a cyclopropyl group, a cyclobutyl group, a cyclopentyl group, and a cyclohexyl group. Examples of the heterocyclic group include a thienyl group, a dioxolane group, a dioxane group, and a benzotriazolyl group. The specific quaternary phosphonium cation may be a homocyclic compound, or may be a heterocyclic compound.

The number of hydrocarbon groups having two or more carbon atoms which is bonded to a phosphorus atom may be 2 or more, may be 3 or more, or may be 4, from the viewpoints of easily obtaining the effect of suppressing the polishing rate for the stopper material (for example, polysilicon) while securing the polishing rate for the material to be removed.

The specific quaternary phosphonium cation may be a monophosphonium cation containing one phosphorus atom, or may be a polyphosphonium cation (for example, diphosphonium cation) containing a plurality of phosphorus atoms.

The specific quaternary phosphonium cation preferably contains a phosphonium cation represented by general formula (I) below, from the viewpoint of further suppressing the polishing rate for the stopper material (for example, polysilicon).

### [Chemical Formula 2]

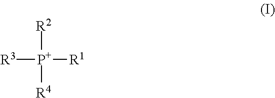

[In formula (I), R¹, R², R³, and R⁴ each independently represent a hydrogen atom or a hydrocarbon group which may have a substituent, at least one of R¹, R², R³, and R⁴ is a hydrocarbon group having two or more carbon atoms which may have a substituent, and phosphorus atoms P in formula (I) may be bonded to each other through R¹, R², R³, or R⁴.]

R¹, R², R³, and R⁴ in general formula (I) each independently represent a hydrogen atom or a substituted or unsubstituted hydrocarbon group. R¹, R², R³, and R⁴ may be the same as or different from each other. A multimer, which is a dimer or more, may be formed by bonding the phosphorus atom of one phosphonium cation represented by general formula (I) and the phosphorus atom of other phosphonium cation represented by general formula (I) through R¹, R², R³, or R⁴.

Examples of the hydrocarbon groups of R¹, R², R³, and R⁴ include hydrocarbon groups described above. The range of the number of carbon atoms of the hydrocarbon groups of R¹, R², R³, and R⁴ is preferably the aforementioned range as the range of the number of carbon atoms of the hydrocarbon group which is bonded to a phosphorus atom. Examples of the substituents of the hydrocarbon groups of R¹, R², R³, and R⁴ include substituents in the substituted hydrocarbon group described above.

From the viewpoints of easily obtaining the effect of suppressing the polishing rate for the stopper material (for example, polysilicon) while securing the polishing rate for the material to be removed, in general formula (I), one or more of R¹, R², R³, and R⁴ may be an unsubstituted hydrocarbon group, two or more of R¹, R², R³, and R⁴ may be an unsubstituted hydrocarbon group, three or more of R¹, R², R³, and R⁴ may be an unsubstituted hydrocarbon group, and all of R¹, R2_{, R}³, and R⁴ may be an unsubstituted hydrocarbon group. The number of the carbon atoms of the unsubstituted hydrocarbon group is preferably 4 or more, more preferably 5 or more, and even more preferably 6 or more, from the viewpoint of further suppressing the polishing rate for the stopper material (for example, polysilicon).

From the viewpoints of easily obtaining the effect of suppressing the polishing rate for the stopper material (for example, polysilicon) while securing the polishing rate for the material to be removed, in general formula (I), one or more of R¹, R², R³, and R⁴ may be an alkyl group, two or more of R¹, R², R³, and R⁴ may be an alkyl group, three or more of R¹, R², R³, and R⁴ may be an alkyl group, and all of R¹, R², R³, and R⁴ may be an alkyl group. The number of the carbon atoms of the alkyl group is preferably 4 or more, more preferably 5 or more, and even more preferably 6 or more, from the viewpoint of further suppressing the polishing rate for the stopper material (for example, polysilicon).

From the viewpoints of easily obtaining the effect of suppressing the polishing rate for the stopper material (for example, polysilicon) while securing the polishing rate for the material to be removed, in general formula (I), one or more of R¹, R², R³, and R⁴ may be an aryl group, two or more of R¹, R², R³, and R⁴ may be an aryl group, three or more of R¹, R², R³, and R⁴ may be an aryl group, and all of R¹, R², R³, and R⁴ may be an aryl group.

As the phosphonium cation represented by general formula (I), from the viewpoint of further suppressing the polishing rate for the stopper material (for example, polysilicon), at least one selected from the group consisting of tributylhexadecylphosphonium cation, tributyl(octyl)phosphonium cation, trihexyl(tetradecyl)phosphonium cation, tetrabutylphosphonium cation, and tetraphenylphosphonium cation is preferred, and tetraphenylphosphonium cation is more preferred.

The polishing liquid containing the specific quaternary phosphonium cation can be obtained, for example, by dissolving a quaternary phosphonium cation salt having the specific quaternary phosphonium cation (hereinafter, referred to as “specific quaternary phosphonium salt” in some cases) in a liquid medium. Examples of a counter anion in the specific quaternary phosphonium salt include hydroxide ions, fluoride ions, chloride ions, bromide ions, iodide ions, hexafluorophosphate ions, tetrafluoroborate ions, tetraphenylborate ions, dicyanamide ions, alkyl phosphate ions (for example, diethyl phosphate ion), hydrogen sulfate ions, dihydrogenphosphate ions, hydrogen phosphate ions, sulfamate ions, perchlorate ions, benzotriazolide anions, and tetratolyl borate anions (for example, tetra-p-tolyl borate anion). As the counter anion, from the viewpoint of further suppressing the polishing rate for the stopper material (for example, polysilicon), at least one selected from the group consisting of chloride ions, bromide ions, and benzotriazolide anions is preferred.

The specific quaternary phosphonium salt preferably contains a compound represented by general formula (Ia) below as the compound having the phosphonium cation represented by general formula (I), from the viewpoint of further suppressing the polishing rate for the stopper material (for example, polysilicon).

### [Chemical Formula 3]

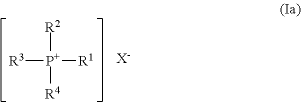

[In formula (Ia), R¹, R², R³, and R⁴ each independently represent a hydrogen atom or a hydrocarbon group which may have a substituent, at least one of R¹, R², R³, and R⁴ is a hydrocarbon group having two or more carbon atoms which may have a substituent, and X⁻ represents an anion.]

Examples of X⁻ in general formula (Ia) include counter anions described above.

Examples of the specific quaternary phosphonium salt that is the compound represented by general formula (Ia) include tetraethylphosphonium bromide, tetraethylphosphonium hexafluorophosphate, tetraethylphosphonium tetrafluoroborate, tributylmethylphosphonium iodide, tributyl(cyanomethyl)phosphonium chloride, tetrakis(hydroxymethyl)phosphonium chloride, tetrakis(hydroxymethyl)phosphonium sulfate, tetrabutylphosphonium hydroxide, tetrabutylphosphonium chloride, tetrabutylphosphonium bromide, tetrabutylphosphonium tetrafluoroborate, tetrabutylphosphonium hexafluorophosphate, tetrabutylphosphonium tetraphenylborate, tributyl(octyl)phosphonium bromide, tetra-n-octylphosphonium bromide, tributyldodecylphosphonium bromide, trihexyl(tetradecyl)phosphonium chloride, trihexyl(tetradecyl)phosphonium dicyanamide, tributylhexadecylphosphonium bromide, methyltriphenylphosphonium chloride, methyltriphenylphosphonium bromide, methyltriphenylphosphonium iodide, tetraphenylphosphonium chloride, tetraphenylphosphonium bromide, tetraphenylphosphonium iodide, tetraphenylphosphonium tetraphenylborate, tetraphenylphosphonium tetra-p-tolyl borate, tributyl(ethyl)phosphonium diethylphosphate, (bromomethyl)triphenylphosphonium bromide, (chloromethyl)triphenylphosphonium chloride, (cyanomethyl)triphenylphosphonium chloride, ethyltriphenylphosphonium chloride, ethyltriphenylphosphonium bromide, ethyltriphenylphosphonium iodide, 2-dimethylamino ethyltriphenylphosphonium bromide, (1,3-dioxolane-2-yl)methyltriphenylphosphonium bromide, 2-(1,3-dioxane-2-yl)ethyltriphenylphosphonium bromide, 2-(1,3-dioxolane-2-yl)ethyltriphenylphosphonium bromide, isopropyltriphenylphosphonium iodide, allyltriphenylphosphonium chloride, allyltriphenylphosphonium bromide, butyltriphenylphosphonium bromide, (formylmethyl)triphenylphosphonium chloride, (methoxymethyl)triphenylphosphonium chloride, triphenylpropylphosphonium bromide, triphenylpropargylphosphonium bromide, amyltriphenylphosphonium bromide, acetonyltriphenylphosphonium chloride, benzyltriphenylphosphonium chloride, benzyltriphenylphosphonium bromide, 4-ethoxybenzyltriphenylphosphonium bromide, 3-bromopropyltriphenylphosphonium bromide, cyclopropyltriphenylphosphonium bromide, hexyltriphenylphosphonium bromide, heptyltriphenylphosphonium bromide, triphenyl(tetradecyl)phosphonium bromide, (tert-butoxycarbonylmethyl)triphenylphosphonium bromide, (4-bromobenzyl)triphenylphosphonium bromide, cinnamyltriphenylphosphonium bromide, (4-chlorobenzyl)triphenylphosphonium chloride, (3-carboxypropyl)triphenylphosphonium bromide, (2-chlorobenzyl)triphenylphosphonium chloride, methoxycarbonylmethyl(triphenyl)phosphonium bromide, ethoxycarbonylmethyl(triphenyl)phosphonium bromide, (1-naphthylmethyl)triphenylphosphonium chloride, phenacyltriphenylphosphonium bromide, (4-carboxybutyl)triphenylphosphonium bromide, (5-carboxypentyl)triphenylphosphonium bromide, (2,4-dichlorobenzyl)triphenylphosphonium chloride, (3,4-dimethoxybenzyl)triphenylphosphonium bromide, (2-hydroxybenzyl)triphenylphosphonium bromide, (4-nitrobenzyl)triphenylphosphonium bromide, tetrabutylphosphonium benzotriazolate, and [(1H-benzotriazole-1-yl)methyl]triphenylphosphonium chloride. Examples of the specific quaternary phosphonium salt other than the compound represented by general formula (Ia) include trans-2-butene-1,4-bis(triphenylphosphonium chloride).

As the specific quaternary phosphonium salt, from the viewpoint of further suppressing the polishing rate for the stopper material (for example, polysilicon), at least one selected from the group consisting of tetrabutylphosphonium bromide, tributylhexadecylphosphonium bromide, tributyl(octyl)phosphonium bromide, trihexyl(tetradecyl)phosphonium chloride, tetrabutylphosphonium benzotriazolate, tetraphenylphosphonium bromide, and tetraphenylphosphonium chloride is preferred, and at least one selected from the group consisting of tetraphenylphosphonium bromide and tetraphenylphosphonium chloride is more preferred.

Examples of a phosphonium cation other than the phosphonium cation represented by general formula (I) include trichloroethylphosphonium cation.

The polishing liquid of the present embodiment may further contain a quaternary phosphonium cation (tetramethylphosphonium cation, tetrachlorophosphonium cation, or the like) other than the specific quaternary phosphonium cation.

The content of the specific quaternary phosphonium salt having the specific quaternary phosphonium cation is preferably in the following range on the basis of the total mass of the polishing liquid. The lower limit of the content of the specific quaternary phosphonium salt is preferably 0.001% by mass or more, more preferably 0.003% by mass or more, even more preferably 0.006% by mass or more, particularly preferably 0.008% by mass or more, extremely preferably 0.01% by mass or more, highly preferably 0.05% by mass or more, still even more preferably 0.08% by mass or more, and more preferably 0.1% by mass or more, from the viewpoint of further suppressing the polishing rate for the stopper material (for example, polysilicon). The upper limit of the content of the specific quaternary phosphonium salt is preferably 1% by mass or less, more preferably 0.5% by mass or less, and even more preferably 0.3% by mass or less, from the viewpoint of being further excellent in the polishing rate for the material to be removed. From these viewpoints, the content of the specific quaternary phosphonium salt is preferably 0.001 to 1% by mass and more preferably 0.001 to 0.5% by mass.

The content of the specific quaternary phosphonium cation in a quaternary phosphonium cation contained in the polishing liquid of the present embodiment is preferably 50% by mass or more, more preferably 70% by mass or more, even more preferably 90% by mass or more, particularly preferably 95% by mass or more, and extremely preferably 98% by mass or more, on the basis of the total mass of a quaternary phosphonium cation (the total amount of the specific quaternary phosphonium cation and a quaternary phosphonium cation other than the specific quaternary phosphonium cation). The content of the specific quaternary phosphonium salt in a quaternary phosphonium salt contained in the polishing liquid of the present embodiment is preferably 50% by mass or more, more preferably 70% by mass or more, even more preferably 90% by mass or more, particularly preferably 95% by mass or more, and extremely preferably 98% by mass or more, on the basis of the total mass of a quaternary phosphonium salt (the total amount of the specific quaternary phosphonium salt and a quaternary phosphonium salt other than the specific quaternary phosphonium salt).

[Other Additives]

The polishing liquid of the present embodiment may further contain other additives not corresponding to the compound having the quaternary phosphonium cation. Examples of the additives include a water-soluble polymer and a pH adjusting agent.

The “water-soluble polymer” is defined as a polymer that dissolves in an amount of 0.1 g or more in 100 g of water at 25° C. By using the water-soluble polymer, polishing characteristics such as a polishing rate, flatness, in-plane uniformity, and the polishing selectivity of the material to be removed with respect to the stopper material (for example, polysilicon) (polishing rate for the material to be removed/polishing rate of the stopper material (for example, polysilicon)) can be adjusted.

Specific examples of the water-soluble polymer include polysaccharides such as alginic acid, pectic acid, carboxymethyl cellulose, agar, curdlan, and guar gum; and vinyl-based polymers such as polyvinylpyrrolidone and polyacrolein. The water-soluble polymers can be used singly or in combination of two or more kinds thereof.

By using the pH adjusting agent, the pH of the polishing liquid can be adjusted. Examples of the pH adjusting agent include acid components such as an inorganic acid and an organic acid; and alkaline components such as ammonia, sodium hydroxide, tetramethylammonium hydroxide (TMAH), imidazole, alkanolamine (for example, trishydroxymethyl aminomethane), triazine (for example, 1,3,5 -tris(dimethylaminopropyl)hexahydro-1,3,5-triazine). Furthermore, the polishing liquid of the present embodiment may contain a buffering agent for stabilizing pH. A buffering agent may be added as a buffer solution (a liquid containing a buffering agent). Examples of such a buffer solution include an acetate buffer solution and a phthalate buffer solution.

(Liquid Medium)

The polishing liquid of the present embodiment contains a liquid medium. As the liquid medium, water can be used. Examples of water include deionized water and ultrapure water. The content of the liquid medium may correspond to the remaining of the polishing liquid from which the contents of other constituent components are removed.

(Properties of Polishing Liquid)

The lower limit of the pH of the polishing liquid of the present embodiment is preferably 2.0 or more, more preferably 2.5 or more, even more preferably 3.0 or more, particularly preferably 3.5 or more, and extremely preferably 4.0 or more, from the viewpoint of further improving the polishing rate for the material to be removed (for example, an insulating material). The upper limit of the pH of the polishing liquid of the present embodiment is preferably 12.0 or less, more preferably 10.0 or less, even more preferably 8.0 or less, particularly preferably less than 8.0, extremely preferably 7.5 or less, and highly preferably 7.0 or less, from the viewpoint of further improving the polishing suppression effect of a stopper material (for example, polysilicon). The pH of the polishing liquid is preferably 2.0 to 12.0 from the viewpoints of suppressing progression of dishing on a surface to be polished and occurrence of polishing scratches while further improving the polishing selectivity of a material to be removed with respect to a stopper material (for example, polysilicon). Furthermore, the pH of the polishing liquid is more preferably 3.0 to 8.0 from the viewpoint of being further excellent in storage stability of the polishing liquid and the polishing suppression effect of a stopper material (for example, polysilicon). The pH of the polishing liquid is defined as the pH at a liquid temperature of 25° C.

The pH of the polishing liquid of the present embodiment can be measured with a pH meter (for example, Product No. PHL-40 manufactured by DKK-TOA CORPORATION). Specifically, for example, a pH meter is subjected to two-point calibration using a phthalate pH buffer solution (pH: 4.01) and a neutral phosphate pH buffer solution (pH: 6.86) as standard buffer solutions, subsequently the electrode of the pH meter is introduced into the polishing liquid, and the value upon stabilization after an elapse of 2 min or longer is measured. At this time, both the liquid temperatures of the standard buffer solutions and the polishing liquid are set to 25° C.

The polishing liquid of the present embodiment may be stored as one-pack polishing liquid containing at least abrasive grains, the specific quaternary phosphonium cation, and a liquid medium, and may be stored as a multi-pack (for example, two-pack) polishing liquid set while the constituent components of the polishing liquid are divided into a plurality of liquids. The polishing liquid of the present embodiment may be stored, for example, as a polishing liquid set while the constituent components of the polishing liquid are divided into a slurry and an additive liquid so that the slurry (first liquid) and the additive liquid (second liquid) are mixed to obtain the polishing liquid. The slurry contains, for example, at least abrasive grains. The additive liquid contains, for example, at least the specific quaternary phosphonium cation. The specific quaternary phosphonium cation and other additives (for example, a water-soluble polymer and a buffering agent) are preferably contained in the additive liquid among the slurry and the additive liquid. Incidentally, the constituent components of the polishing liquid may also be stored as a polishing liquid set divided into three or more liquids. For example, the constituent components of the polishing liquid may be stored to be divided into a slurry containing abrasive grains and a liquid medium, an additive liquid containing the specific quaternary phosphonium cation and a liquid medium, and an additive liquid containing other additives and a liquid medium.

With regard to the above-described polishing liquid set, the slurry and the additive liquid are mixed immediately before polishing or during polishing, and thus a polishing liquid is produced. Furthermore, the one-pack polishing liquid may be stored as a stock solution for a polishing liquid, in which the content of the liquid medium has been reduced, and may be used after being diluted with the liquid medium during polishing. The multi-pack polishing liquid set may be stored as a stock solution for a slurry and a stock solution for an additive liquid, in both of which the content of the liquid medium has been reduced, and may be used after being diluted with the liquid medium during polishing.

<Polishing Method>

The polishing method of the present embodiment may include a polishing step of polishing a surface to be polished by using the above-described one-pack polishing liquid or may include a polishing step of polishing a surface to be polished by using a polishing liquid obtained by mixing the slurry and the additive liquid of the above-described polishing liquid set.

The surface to be polished may contain a stopper material. The surface to be polished may contain a stopper material and a material to be removed (for example, an insulating material), or may contain a stopper material and at least one selected from the group consisting of silicon oxide and silicon nitride. The polishing method of the present embodiment may include, for example, a polishing step of selectively polishing a material to be removed with respect to a stopper material using the above-described one-pack polishing liquid or a polishing liquid obtained by mixing the slurry and the additive liquid of the above-described polishing liquid set. The expression “selectively polishing a material A with respect to a material B” means that a polishing rate for the material A is higher than a polishing rate for the material B in the same polishing conditions. The polishing rate ratio of silicon oxide with respect to polysilicon is preferably 6.0 or more, more preferably 10 or more, and even more preferably 15 or more. The polishing rate ratio of silicon nitride with respect to polysilicon is preferably 1.5 or more, more preferably 2.0 or more, and even more preferably 3.0 or more. The polishing rate of polysilicon is preferably 25 nm/min or less, more preferably 20 nm/min or less, even more preferably 15 nm/min or less, particularly preferably 10 nm/min or less, and extremely preferably 5 nm/min or less.

Examples of the material to be removed include an insulating material (excluding a stopper material). Examples of the insulating material include silicon oxide and silicon nitride. Examples of the stopper material include polysilicon, amorphous silicon, and crystalline silicon. The amorphous silicon and the crystalline silicon show the surface states (wettability, a zeta potential, and the like) similar to those of polysilicon.

Examples of a method for producing a material to be removed and a stopper material include CVD methods such as a low-pressure CVD method, a quasi-normal pressure CVD method, and a plasma CVD method; and a spin coating method of applying a liquid raw material on a rotating substrate.

Each of the material to be removed and the stopper material may be a single material or may be a plurality of materials. In a case where a plurality of materials are exposed to the surface to be polished, these can be regarded as the material to be removed and the stopper material. The material to be removed and the stopper material may be in the form of a film, and may be a silicon oxide film, a silicon nitride film, a polysilicon film, or the like.

The surface to be polished may contain polysilicon. The surface to be polished may contain polysilicon and a material to be removed (for example, an insulating material), or may contain polysilicon and at least one selected from the group consisting of silicon oxide and silicon nitride. The polishing method of the present embodiment may include, for example, a polishing step of selectively polishing a material to be removed with respect to polysilicon using the above-described one-pack polishing liquid or a polishing liquid obtained by mixing the slurry and the additive liquid of the above-described polishing liquid set.

The polishing method of the present embodiment may be a method for polishing a base substrate. The base substrate has, for example, a stopper (a member containing a stopper material). The base substrate may have, for example, a stopper and a member containing a material to be removed. In the present embodiment, polishing of a base substrate, which has a stopper containing a stopper material (for example, polysilicon) and a member containing an insulating material (for example, silicon oxide), can be stopped by the stopper. According to the present embodiment, it is possible to provide a polishing method of a base substrate having a material to be removed (for example, an insulating material) and a stopper material, the polishing method including a step of selectively polishing the material to be removed with respect to the stopper material by using the aforementioned polishing liquid. According to the present embodiment, it is possible to provide a polishing method of a base substrate having a material to be removed (for example, an insulating material) and a stopper material, the polishing method including a step of selectively polishing the material to be removed with respect to the stopper material by using a polishing liquid obtained by mixing the slurry and the additive liquid of the aforementioned polishing liquid set.

As the base substrate which is an object to be polished, substrates and the like are mentioned, and examples thereof include substrates on which a member containing a material to be removed and a stopper are formed on substrates used in production of semiconductor elements (for example, semiconductor substrates on which an STI pattern, a gate pattern, a wiring pattern, or the like is formed).

In the polishing step, for example, in a state where a surface to be polished of a base substrate is pressed against a polishing pad of a polishing platen, the above-described polishing liquid is supplied between the surface to be polished and the polishing pad, and the base substrate and the polishing platen are relatively moved to polish the surface to be polished. In the polishing step, for example, at least a part of the material to be removed in the surface to be polished is removed by polishing.

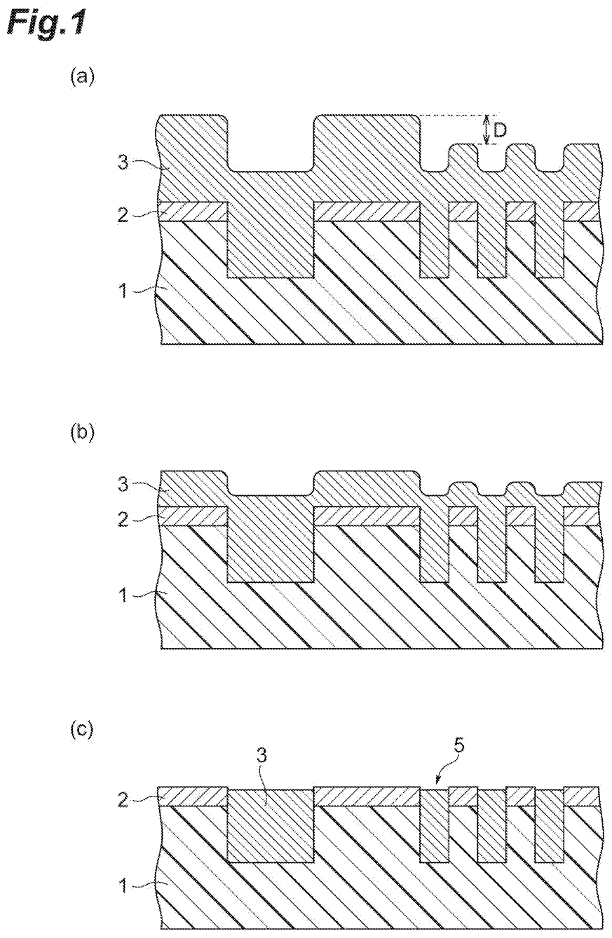

FIG. 1 is a schematic cross-sectional view illustrating a polishing step when an STI structure of a semiconductor is formed. FIG. 1(a) is a schematic cross-sectional view illustrating a base substrate before polishing. FIG. 1(b) is a schematic cross-sectional view illustrating the base substrate during polishing. FIG. 1(c) is a schematic cross-sectional view illustrating the base substrate after polishing. As illustrated in FIG. 1(a), the base substrate has a substrate (for example, a semiconductor substrate such as a silicon substrate) 1 having a concavo-convex pattern, a stopper 2 disposed on the convex portion of the substrate 1, and an insulating film 3 disposed on the substrate 1 and the stopper 2 so as to embed the concave portion. A difference D is formed on the surface of the insulating film 3. As illustrated in FIG. 1(b), in the polishing process, an unnecessary region partially protruding on the surface of the insulating film 3 is preferentially removed by CMP so as to eliminate the difference D of the insulating film 3. In such polishing, polishing of the insulating film 3 is stopped by the stopper 2 at the stage in which the stopper 2 is exposed as illustrated in FIG. 1(c), and an STI structure having an embedded portion 5 is formed.

In this way, while irregularities on the surface of the material to be removed are eliminated by polishing a material to be removed (for example, an insulating material) formed on the substrate by the aforementioned polishing liquid to remove an excess portion, the material to be removed is prevented from being excessively polished by stopping polishing when the stopper is exposed, and thus, a flat and smooth surface can be obtained over the entire surface of the material to be removed. The polishing liquid of the present embodiment can be used for polishing a surface to be polished containing a stopper material (for example, polysilicon). The polishing liquid of the present embodiment can be used for polishing a surface to be polished containing at least one of silicon oxide and silicon nitride.

In the polishing method of the present embodiment, as a polishing apparatus, it is possible to use a general polishing apparatus which has a holder capable of holding a base substrate (for example, a semiconductor substrate) having a surface to be polished and a polishing platen to which a polishing pad can be attached. A motor or the like in which the number of rotations can be changed is attached to each of the holder and the polishing platen. As the polishing apparatus, for example, a polishing apparatus (trade name: Reflexion) manufactured by Applied Materials, Inc. or a polishing apparatus (trade name: F-REX) manufactured by EBARA CORPORATION can be used.

As the polishing pad, a general nonwoven fabric, a foamed body, a non-foamed body, or the like can be used. As the material for the polishing pad, resins such as a polyurethane, an acrylic resin, a polyester, an acryl-ester copolymer, polytetrafluoroethylene, polypropylene, polyethylene, poly-4-methylpentene, cellulose, a cellulose ester, a polyamide (for example, NYLON and aramid), a polyimide, a polyimideamide, a polysiloxane copolymer, an oxirane compound, a phenolic resin, polystyrene, a polycarbonate, or an epoxy resin can be used. Particularly, from the viewpoint of polishing rate and flatness, the material for the polishing pad is preferably a foamed polyurethane and a non-foamed polyurethane. The polishing pad may be subjected to groove processing, by which the polishing liquid accumulates thereon.

There are no limitations on the polishing conditions; however, the rotation speed (the number of rotations) of the polishing platen is preferably 200 min⁻¹ or less so that the base substrate does not fly away, and the polishing pressure (processing load) applied to the base substrate is preferably 100 kPa or less, from the viewpoint of sufficiently suppressing the occurrence of polishing scratches. During polishing, it is preferable to supply the polishing liquid continuously to the polishing pad using a pump or the like. There are no limitations on the supply amount for this, however, it is preferable that the surface of the polishing pad is always covered with the polishing liquid.

It is preferable that the base substrate after the completion of polishing is thoroughly washed under flowing water, and thereby particles adhering to the base substrate are removed. For the washing, in addition to pure water, chemical for washing such as dilute hydrofluoric acid or aqueous ammonia may be used, and a brush may be used in order to increase the washing efficiency. Furthermore, after washing, it is preferable that water droplets adhering to the base substrate are dropped by using a spin dryer or the like, and then the base substrate is dried.

The polishing liquid, the polishing liquid set, and the polishing method of the present embodiment can be used, for example, in the formation step of STI, polishing of pre-metal insulating materials, interlayer insulating materials, or the like. As the pre-metal insulating material, other than silicon oxide, for example, phosphorus-silicate glass, boron-phosphorus-silicate glass, silicon oxyfluoride, fluorinated amorphous carbon, and the like can be used.

The polishing liquid, the polishing liquid set, and the polishing method of the present embodiment can be applied not only to film-like objects to be polished, but also various substrates composed of glass, silicon, SiC, SiGe, Ge, GaN, GaP, GaAs, sapphire, plastics, or the like.

The polishing liquid, the polishing liquid set, and the polishing method of the present embodiment can be used not only for the production of semiconductor elements, but also for the production of image display devices such as TFT liquid crystal or organic EL; optical components such as a photomask, a lens, a prism, an optical fiber, or a single crystal scintillator; optical elements such as an optical switching element or an optical waveguide; light-emitting elements such as a solid laser or a blue laser LED; and magnetic storage devices such as a magnetic disc or a magnetic head.

### EXAMPLES

Hereinafter, the present invention will be specifically described based on Examples; however, the present invention is not limited to these.

<Preparation of Abrasive Grains>

(Abrasive Grains Containing Hydroxide of Tetravalent Metal Element)

[Synthesis of Hydroxide of Tetravalent Metal Element]

350 g of a 50% by mass aqueous solution of Ce(NH₄)₂(NO₃)₆ (manufactured by NIHON KAGAKU SANGYO CO., LTD., trade name: CANSO liquid) was mixed with 7825 g of pure water, and thereby a solution was obtained. Next, while this solution was stirred, 750 g of an aqueous solution of imidazole (10% by mass aqueous solution, 1.47 mol/L) was added dropwise thereto at a mixing rate of 5 mL/min, and thereby a precipitate containing cerium hydroxide was obtained. The synthesis of cerium hydroxide was performed at a temperature of 25° C. at a stirring speed of 400 min⁻¹. Stirring was performed using a three-blade pitch paddle having a total blade length of 5 cm.

The obtained precipitate (precipitate containing cerium hydroxide) was centrifuged (4000 min⁻¹, for 5 minutes), subsequently the liquid phase was removed by decantation to perform solid-liquid separation. 10 g of the particles obtained by the solid-liquid separation were mixed with 990 g of water, and then the particles were dispersed in water using an ultrasonic cleaner, thereby a cerium hydroxide slurry (the content of particles: 1.0% by mass) containing abrasive grains that contained cerium hydroxide (hereinafter, referred to as “cerium hydroxide particles”) was prepared.

[Structural Analysis of Abrasive Grains]

An adequate amount of the cerium hydroxide slurry was collected and dried in a vacuum, and thereby the abrasive grains were isolated, and then, sufficient washing was performed with pure water to obtain a sample. For the sample thus obtained, measurement was performed according to an FT-IR ATR method, and a peak based on nitrate ion (NO₃⁻) was observed in addition to a peak based on hydroxide ion (OH⁻). Furthermore, for the same sample, XPS (N-XPS) measurement for nitrogen was performed, and a peak based on NH₄⁺ was not observed, while a peak based on nitrate ion was observed. From these results, it was confirmed that the abrasive grains contained in the cerium hydroxide slurry contained, at least in a portion, particles having nitrate ion bonded to cerium element. Furthermore, since particles having hydroxide ion bonded to cerium element were contained at least in a portion of the abrasive grains, it was confirmed that the abrasive grains contained cerium hydroxide. From these results, it was confirmed that hydroxide of cerium contained hydroxide ion bonded to cerium element.

[Measurement of Absorbance and Light Transmittance]

An adequate amount of the cerium hydroxide slurry was collected and diluted with water such that the content of abrasive grains became 0.0065% by mass (65 ppm), and thus, a measurement sample (aqueous dispersion liquid) was obtained. About 4 mL of this measurement sample was introduced into a 1-cm square cell, and the cell was placed in a spectrophotometer (apparatus name: U3310) manufactured by Hitachi, Ltd. Measurement of the absorbance in a wavelength range of 200 to 600 nm was performed, and the absorbance for light having a wavelength of 290 nm and the absorbance for light having a wavelength of 450 to 600 nm were measured. The absorbance for light having a wavelength of 290 nm was 1.192, and the absorbance for light having a wavelength of 450 to 600 nm was less than 0.010.

About 4 mL of the cerium hydroxide slurry (the content of particles: 1.0% by mass) was introduced into a 1-cm square cell, and the cell was placed in a spectrophotometer (apparatus name: U3310) manufactured by Hitachi, Ltd. Measurement of the absorbance in a wavelength range of 200 to 600 nm was performed, and the absorbance for light having a wavelength of 400 nm and the light transmittance for light having a wavelength of 500 nm were measured. The absorbance for light having a wavelength of 400 nm was 2.25, and the light transmittance for light having a wavelength of 500 nm was 92%/cm.

(Abrasive Grains Containing Cerium Oxide)

As an aqueous dispersion liquid of abrasive grains containing cerium oxide (hereinafter, referred to as “cerium oxide particles”) (the content of cerium oxide particles: 30% by mass), colloidal ceria (trade name: Zenus (registered trademark) HC60) manufactured by Solvay was prepared.

<Preparation of CMP Polishing Liquid>

### Example 1

50 g of the aforementioned cerium hydroxide slurry, 10 g of an additive liquid containing 1% by mass of tributylhexadecylphosphonium bromide and 99% by mass of water, acetic acid, and water were mixed, and thereby 1000 g of a CMP polishing liquid containing 0.05% by mass of cerium hydroxide particles and 0.01% by mass of tributylhexadecylphosphonium bromide was prepared. The pH of the CMP polishing liquid was appropriately adjusted using acetic acid so as to be 4.0.

### Example 2

50 g of the aforementioned cerium hydroxide slurry, 10 g of an additive liquid containing 1% by mass of tributyl(octyl)phosphonium bromide and 99% by mass of water, acetic acid, and water were mixed, and thereby 1000 g of a CMP polishing liquid containing 0.05% by mass of cerium hydroxide particles and 0.01% by mass of tributyl(octyl)phosphonium bromide was prepared. The pH of the CMP polishing liquid was appropriately adjusted using acetic acid so as to be 4.0.

### Example 3

50 g of the aforementioned cerium hydroxide slurry, 10 g of an additive liquid containing 1% by mass of trihexyl(tetradecyl)phosphonium chloride and 99% by mass of water, acetic acid, and water were mixed, and thereby 1000 g of a CMP polishing liquid containing 0.05% by mass of cerium hydroxide particles and 0.01% by mass of trihexyl(tetradecyl)phosphonium chloride was prepared. The pH of the CMP polishing liquid was appropriately adjusted using acetic acid so as to be 4.0.

### Example 4

50 g of the aforementioned cerium hydroxide slurry, 10 g of an additive liquid containing 1% by mass of tetrabutylphosphonium benzotriazolate and 99% by mass of water, acetic acid, and water were mixed, and thereby 1000 g of a CMP polishing liquid containing 0.05% by mass of cerium hydroxide particles and 0.01% by mass of tetrabutylphosphonium benzotriazolate was prepared. The pH of the CMP polishing liquid was appropriately adjusted using acetic acid so as to be 4.0.

### Example 5

50 g of the aforementioned cerium hydroxide slurry, 10 g of an additive liquid containing 1% by mass of tetraphenylphosphonium bromide and 99% by mass of water, acetic acid, and water were mixed, and thereby 1000 g of a CMP polishing liquid containing 0.05% by mass of cerium hydroxide particles and 0.01% by mass of tetraphenylphosphonium bromide was prepared. The pH of the CMP polishing liquid was appropriately adjusted using acetic acid so as to be 4.0.

### Example 6

50 g of the aforementioned cerium hydroxide slurry, 10 g of an additive liquid containing 1% by mass of tetraphenylphosphonium chloride and 99% by mass of water, acetic acid, and water were mixed, and thereby 1000 g of a CMP polishing liquid containing 0.05% by mass of cerium hydroxide particles and 0.01% by mass of tetraphenylphosphonium chloride was prepared. The pH of the CMP polishing liquid was appropriately adjusted using acetic acid so as to be 4.0.

### Example 7

50 g of the aforementioned cerium hydroxide slurry, 10 g of an additive liquid containing 1% by mass of tetrabutylphosphonium bromide and 99% by mass of water, acetic acid, and water were mixed, and thereby 1000 g of a CMP polishing liquid containing 0.05% by mass of cerium hydroxide particles and 0.01% by mass of tetrabutylphosphonium bromide was prepared. The pH of the CMP polishing liquid was appropriately adjusted using acetic acid so as to be 4.0.

### Example 8

50 g of the aforementioned cerium hydroxide slurry, 5 g of an additive liquid containing 1% by mass of tributylhexadecylphosphonium bromide and 99% by mass of water, acetic acid, and water were mixed, and thereby 1000 g of a CMP polishing liquid containing 0.05% by mass of cerium hydroxide particles and 0.005% by mass of tributylhexadecylphosphonium bromide was prepared. The pH of the CMP polishing liquid was appropriately adjusted using acetic acid so as to be 4.0.

### Example 9

50 g of the aforementioned cerium hydroxide slurry, 100 g of an additive liquid containing 1% by mass of tributylhexadecylphosphonium bromide and 99% by mass of water, acetic acid, and water were mixed, and thereby 1000 g of a CMP polishing liquid containing 0.05% by mass of cerium hydroxide particles and 0.1% by mass of tributylhexadecylphosphonium bromide was prepared. The pH of the CMP polishing liquid was appropriately adjusted using acetic acid so as to be 4.0.

### Example 10

50 g of the aforementioned cerium hydroxide slurry, 5 g of an additive liquid containing 1% by mass of tetraphenylphosphonium bromide and 99% by mass of water, acetic acid, and water were mixed, and thereby 1000 g of a CMP polishing liquid containing 0.05% by mass of cerium hydroxide particles and 0.005% by mass of tetraphenylphosphonium bromide was prepared. The pH of the CMP polishing liquid was appropriately adjusted using acetic acid so as to be 4.0.

### Example 11

50 g of the aforementioned cerium hydroxide slurry, 100 g of an additive liquid containing 1% by mass of tetraphenylphosphonium bromide and 99% by mass of water, acetic acid, and water were mixed, and thereby 1000 g of a CMP polishing liquid containing 0.05% by mass of cerium hydroxide particles and 0.1% by mass of tetraphenylphosphonium bromide was prepared. The pH of the CMP polishing liquid was appropriately adjusted using acetic acid so as to be 4.0.

### Example 12

50 g of the aforementioned cerium hydroxide slurry, 10 g of an additive liquid containing 1% by mass of tributylhexadecylphosphonium bromide and 99% by mass of water, acetic acid, and water were mixed, and thereby 1000 g of a CMP polishing liquid containing 0.05% by mass of cerium hydroxide particles and 0.01% by mass of tributylhexadecylphosphonium bromide was prepared. The pH of the CMP polishing liquid was appropriately adjusted using acetic acid so as to be 3.4.

### Example 13

50 g of the aforementioned cerium hydroxide slurry, 10 g of an additive liquid containing 1% by mass of tributylhexadecylphosphonium bromide and 99% by mass of water, acetic acid, and water were mixed, and thereby 1000 g of a CMP polishing liquid containing 0.05% by mass of cerium hydroxide particles and 0.01% by mass of tributylhexadecylphosphonium bromide was prepared. The pH of the CMP polishing liquid was appropriately adjusted using acetic acid so as to be 7.0.

### Example 14

50 g of the aforementioned cerium hydroxide slurry, 10 g of an additive liquid containing 1% by mass of tetraphenylphosphonium bromide and 99% by mass of water, acetic acid, and water were mixed, and thereby 1000 g of a CMP polishing liquid containing 0.05% by mass of cerium hydroxide particles and 0.01% by mass of tetraphenylphosphonium bromide was prepared. The pH of the CMP polishing liquid was appropriately adjusted using acetic acid so as to be 3.4.

### Example 15

50 g of the aforementioned cerium hydroxide slurry, 10 g of an additive liquid containing 1% by mass of tetraphenylphosphonium bromide and 99% by mass of water, acetic acid, and water were mixed, and thereby 1000 g of a CMP polishing liquid containing 0.05% by mass of cerium hydroxide particles and 0.01% by mass of tetraphenylphosphonium bromide was prepared. The pH of the CMP polishing liquid was appropriately adjusted using acetic acid so as to be 7.0.

### Comparative Example 1

50 g of the aforementioned cerium hydroxide slurry, acetic acid, and water were mixed, and thereby 1000 g of a CMP polishing liquid containing 0.05% by mass of cerium hydroxide particles was prepared. The pH of the CMP polishing liquid was appropriately adjusted using acetic acid so as to be 4.0.

### Comparative Example 2

50 g of the aforementioned cerium hydroxide slurry, 10 g of an additive liquid containing 1% by mass of benzyltrimethylammonium chloride and 99% by mass of water, acetic acid, and water were mixed, and thereby 1000 g of a CMP polishing liquid containing 0.05% by mass of cerium hydroxide particles and 0.01% by mass of benzyltrimethylammonium chloride was prepared. The pH of the CMP polishing liquid was appropriately adjusted using acetic acid so as to be 4.0.

### Comparative Example 3

50 g of the aforementioned cerium hydroxide slurry, 10 g of an additive liquid containing 1% by mass of hexyltrimethylammonium bromide and 99% by mass of water, acetic acid, and water were mixed, and thereby 1000 g of a CMP polishing liquid containing 0.05% by mass of cerium hydroxide particles and 0.01% by mass of hexyltrimethylammonium bromide was prepared. The pH of the CMP polishing liquid was appropriately adjusted using acetic acid so as to be 4.0.

### Comparative Example 4

50 g of the aforementioned cerium hydroxide slurry, 10 g of an additive liquid containing 1% by mass of tetramethylammonium bromide and 99% by mass of water, acetic acid, and water were mixed, and thereby 1000 g of a CMP polishing liquid containing 0.05% by mass of cerium hydroxide particles and 0.01% by mass of tetramethylammonium bromide was prepared. The pH of the CMP polishing liquid was appropriately adjusted using acetic acid so as to be 4.0.

### Comparative Example 5

50 g of the aforementioned cerium hydroxide slurry, 10 g of an additive liquid containing 1% by mass of tetramethylphosphonium bromide and 99% by mass of water, acetic acid, and water were mixed, and thereby 1000 g of a CMP polishing liquid containing 0.05% by mass of cerium hydroxide particles and 0.01% by mass of tetramethylphosphonium bromide was prepared. The pH of the CMP polishing liquid was appropriately adjusted using acetic acid so as to be 4.0.

### Comparative Example 6

50 g of the aforementioned cerium hydroxide slurry, 10 g of an additive liquid containing 1% by mass of tetrabutylammonium bromide and 99% by mass of water, acetic acid, and water were mixed, and thereby 1000 g of a CMP polishing liquid containing 0.05% by mass of cerium hydroxide particles and 0.01% by mass of tetrabutylammonium bromide was prepared. The pH of the CMP polishing liquid was appropriately adjusted using acetic acid so as to be 4.0.

### Example 16

8.33 g of the aforementioned aqueous dispersion liquid of cerium oxide particles, 10 g of an additive liquid containing 1% by mass of tributylhexadecylphosphonium bromide and 99% by mass of water, acetic acid, and water were mixed, and thereby 1000 g of a CMP polishing liquid containing 0.25% by mass of cerium oxide and 0.01% by mass of tributylhexadecylphosphonium bromide was prepared. The pH of the CMP polishing liquid was appropriately adjusted using acetic acid so as to be 4.5.

### Example 17

33 g of the aforementioned aqueous dispersion liquid of cerium oxide particles, 10 g of an additive liquid containing 1% by mass of tetraphenylphosphonium bromide and 99% by mass of water, acetic acid, and water were mixed, and thereby 1000 g of a CMP polishing liquid containing 0.25% by mass of cerium oxide particles and 0.01% by mass of tetraphenylphosphonium bromide was prepared. The pH of the CMP polishing liquid was appropriately adjusted using acetic acid so as to be 4.5.

### Comparative Example 7

The aforementioned aqueous dispersion liquid of cerium oxide particles, acetic acid, and water were mixed, and thereby 1000 g of a CMP polishing liquid containing 0.25% by mass of cerium oxide particles was prepared. The pH of the CMP polishing liquid was appropriately adjusted using acetic acid so as to be 4.5.

<Liquid Property Evaluation>

The pH of the CMP polishing liquid and the average particle size of the abrasive grains were evaluated under the following conditions.

(pH)

Measurement temperature: 25±5° C.

Measurement apparatus: Product No.: PHL-40 manufactured by DKK-TOA CORPORATION

Measurement method: After performing 2-point calibration using a standard buffer solution (phthalate pH buffer solution, pH: 4.01 (25° C.); neutral phosphate pH buffer solution, pH: 6.86 (25° C.)), an electrode was placed in the CMP polishing liquid, and the pH upon stabilization after an elapse of 2 min or longer was measured using the above-described measurement apparatus.

(Average Particle Size of Cerium Hydroxide Particles)

The average particle size of the abrasive grains (abrasive grains containing cerium hydroxide) in the cerium hydroxide slurry was measured using apparatus name: N5 manufactured by Beckman Coulter, Inc., and the average particle size was 7 nm. The measurement method is as follows. First, about 1 mL of a measurement sample (cerium hydroxide slurry, aqueous dispersion liquid) containing 1.0% by mass of abrasive grains was introduced into a 1-cm square cell, and the cell was placed in N5. As the measurement sample information of the N5 software, the refractive index was set to 1.333 and the viscosity of the dispersing medium was set to 0.887 mPa·s, and measurement was performed at 25° C., and then, the value displayed as Unimodal Size Mean was read out.

(Average Particle Size of Cerium Oxide Particles)

The average particle size of the abrasive grains (abrasive grains containing cerium oxide) in the aqueous dispersion liquid of the cerium oxide particles was measured by using a laser diffraction scattering type microtrack particle size distribution meter (manufactured by NIKKISO CO., LTD., apparatus name: MT-3000II), and the average particle size was 175 nm. The measurement method is as follows. Water (refractive index: 1.33) as a solvent was circulated, the above-described aqueous dispersion liquid was added to the above-described solvent until the dv value of the sample concentration (diffraction light amount; an indication of measurement concentration in the microtrack) was in a range of 0.0010 to 0.0011, measurement was then performed, and the average particle size (MV) was measured.

<CMP Evaluation>

A wafer for CMP evaluation was polished by using the above-described CMP polishing liquid under the following polishing conditions.

(CMP Polishing Conditions)

In polishing of the wafer for CMP evaluation, a polishing apparatus (trade name: F-REX300) manufactured by EBARA CORPORATION was used. The wafer for CMP evaluation was set in a holder mounting an adsorption pad for attachment of the substrate. A polishing cloth (Product No. IC1010 manufactured by The Dow Chemical Company) made of a porous urethane resin was attached to a polishing platen having a diameter of 600 mm of the polishing apparatus. The holder was put on the polishing platen while the surface on which the film to be polished (the silicon oxide film, the silicon nitride film, and the polysilicon film) was disposed faced downwards, and a processing load was set to 14.0 kPa (2.4 psi).

(Wafer for CMP Evaluation)

Blanket wafers having no pattern formed thereon were used as the wafer for CMP evaluation. As the blanket wafers, a wafer having a silicon oxide film on a silicon (Si) substrate (diameter: 300 mm), a wafer having a silicon nitride film on a silicon (Si) substrate (diameter: 300 mm), and a wafer having a polysilicon film on a silicon (Si) substrate (diameter: 300 mm) were used.

While the above-described polishing liquid for CMP was added dropwise onto the above-described polishing platen at a speed of 200 mL/min, the polishing platen and the wafer for CMP evaluation were rotated at 100 min⁻¹ and 107 min⁻¹, respectively, and the wafer for CMP evaluation was polished. The polishing was performed for 30 seconds. Then, the polished wafer was thoroughly washed with pure water using a PVA brush (polyvinyl alcohol brush) and then dried.

(Evaluation)

The film thicknesses of films to be polished (the silicon oxide film, the silicon nitride film, and the polysilicon film) before and after polishing were measured using a light interference type film thickness measuring apparatus (apparatus name: F80) manufactured by Filmetrics, Inc. and the polishing rates of the films to be polished in the blanket wafer were calculated on the basis of an average of change amounts in film thickness. The unit of the polishing rate is nm/min.

The respective measurement results are shown in Tables 1 to 4.

TABLE 1

| | | Example 1 | Example 2 | Example 3 | Example 4 | Example 5 | Example 6 | Example 7 |
|---|---|---|---|---|---|---|---|---|
| Abrasive | Type | Cerium hydroxide | | | | | | |
| grains | Content | 0.05 | | | | | | |
| | [mass %] | | | | | | | |
| Additive | Type | Tributyl | Tributyl | Trihexyl | Tetrabutyl | Tetraphenyl | Tetraphenyl | Tetrabutyl |
| | | hexadecyl | (octyl) | (tetradecyl) | phosphonium | phosphonium | phosphonium | phosphonium |
| | | phosphonium | phosphonium | phosphonium | benzotriazolate | bromide | chloride | bromide |
| | | bromide | bromide | chloride | | | | |
| | Content | 0.01 | | | | | | |
| | [mass %] | | | | | | | |
| pH | | 4.0 | 4.0 | 4.0 | 4.0 | 4.0 | 4.0 | 4.0 |
| Polishing | Silicon | 100 | 130 | 90 | 170 | 140 | 120 | 120 |
| rate | oxide | | | | | | | |
| [nm/min] | Silicon | 33 | 36 | 30 | 37 | 27 | 36 | 35 |
| | nitride | | | | | | | |
| | Polysilicon | 3 | 4 | 6 | 8 | 6 | 4 | 12 |
| Polishing | Silicon | 33 | 33 | 15 | 21 | 23 | 30 | 10 |
| rate ratio | oxide | | | | | | | |
| (vs | Silicon | 11.0 | 9.0 | 5.0 | 4.6 | 4.5 | 9.0 | 2.9 |
| polysilicon) | nitride | | | | | | | |

TABLE 2

| | | Example 8 | Example 9 | Example 10 | Example 11 | Example 12 | Example 13 | Example 14 | Example 15 |
|---|---|---|---|---|---|---|---|---|---|
| Abrasive | Type | Cerium hydroxide | | | | | | | |
| grains | Content | 0.05 | | | | | | | |
| | [mass %] | | | | | | | | |
| Additive | Type | Tributylhexadecyl | | Tetraphenyl | | Tributylhexadecyl | | Tetraphenyl | |
| | | phosphonium | | phosphonium | | phosphonium | | phosphonium | |
| | | bromide | | bromide | | bromide | | bromide | |
| | Content | 0.005 | 0.1 | 0.005 | 0.1 | 0.01 | | | |
| | [mass %] | | | | | | | | |
| pH | | 4.0 | 4.0 | 4.0 | 4.0 | 3.4 | 7.0 | 3.4 | 7.0 |
| Polishing | Silicon | 90 | 120 | 110 | 200 | 90 | 220 | 120 | 200 |
| rate | oxide | | | | | | | | |
| [nm/min] | Silicon | 12 | 10 | 40 | 30 | 10 | 20 | 50 | 30 |
| | nitride | | | | | | | | |
| | Polysilicon | 4 | 0.5 | 4 | 2 | 2 | 6 | 4 | 2 |
| Polishing | Silicon | 23 | 240 | 28 | 100 | 45 | 37 | 30 | 100 |
| rate ratio | oxide | | | | | | | | |
| (vs | Silicon | 3.0 | 20 | 10 | 15 | 5.0 | 3.3 | 13 | 15 |
| polysilicon) | nitride | | | | | | | | |

TABLE 3

| | | Comparative | Comparative | Comparative | Comparative | Comparative | Comparative |
|---|---|---|---|---|---|---|---|
| | | Example 1 | Example 2 | Example 3 | Example 4 | Example 5 | Example 6 |
| Abrasive | Type | Ceriumhycroxide | | | | | |
| grains | Content | 0.05 | | | | | |
| | [mass %] | | | | | | |
| Additive | Type | — | Benzyltrimethyl | Hexyltrimethyl | Tetramethyl | Tetramethyl | Tetrabutyl |
| | | | ammonium | ammonium | ammonium | phosphonium | ammonium |
| | | | chloride | bromide | bromide | bromide | bromide |
| | Content | 0 | 0.01 | | | | |
| | [mass %] | | | | | | |
| pH | | 4.0 | 4.0 | 4.0 | 4.0 | 4.0 | 4.0 |
| Polishing | Silicon | 100 | 110 | 120 | 140 | 140 | 100 |
| rate | oxide | | | | | | |
| [nm/min] | Silicon | 35 | 40 | 32 | 30 | 35 | 35 |
| | nitride | | | | | | |
| | Polysilicon | 50 | 50 | 50 | 70 | 75 | 30 |
| Polishing | Silicon | 2.0 | 2.2 | 2.4 | 2.0 | 1.9 | 3.3 |
| rate ratio | oxide | | | | | | |
| (vs | Silicon | 0.7 | 0.8 | 0.6 | 0.4 | 0.5 | 1.2 |
| polysilicon) | nitride | | | | | | |

TABLE 4

| | | | | Compar- |
|---|---|---|---|---|
| | | | | ative Ex- |
| | | Example 16 | Example 17 | ample 7 |
| Abrasive | Type | Cerium oxide | | |
| grains | Content | 0.25 | | |
| | [mass %] | | | |
| Additive | Type | Tributyl- | Tetraphenyl | — |
| | | hexadecyl | phosphonium | |
| | | phosphonium | bromide | |
| | | bromide | | |
| | Content | 0.01 | | 0 |
| | [mass %] | | | |
| pH | | 4.5 | 4.5 | 4.5 |
| Polishing | Silicon | 240 | 240 | 220 |
| rate | oxide | | | |
| [nm/min] | Silicon | 30 | 30 | 50 |
| | nitride | | | |
| | Polysilicon | 2 | 2 | 40 |
| Polishing | Silicon | 120 | 120 | 5.5 |
| rate ratio | oxide | | | |
| (vs | Silicon | 15 | 15 | 1.3 |
| polysilicon) | nitride | | | |

As shown in Tables 1 to 4, it is found that, in Examples using abrasive grains containing a metal hydroxide or cerium oxide and a quaternary phosphonium cation having a hydrocarbon group having two or more carbon atoms which is bonded to a phosphorus atom, as compared to Comparative Examples, the polishing rate for polysilicon can be suppressed while securing the polishing rate for the insulating material.

### REFERENCE SIGNS LIST

1: substrate, 2: stopper, 3: insulating film, 5: embedded portion, D: difference.

1. A polishing liquid comprising:
abrasive grains;
a quaternary phosphonium cation; and
a liquid medium, wherein
the abrasive grains contain a metal hydroxide, and
the quaternary phosphonium cation has a hydrocarbon group having two or more carbon atoms which is bonded to a phosphorus atom.

2. The polishing liquid according to claim 1, wherein the metal hydroxide contains cerium hydroxide.

3. A polishing liquid comprising:
abrasive grains;
a quaternary phosphonium cation; and
a liquid medium, wherein
the abrasive grains contain cerium oxide, and
the quaternary phosphonium cation has a hydrocarbon group having two or more carbon atoms which is bonded to a phosphorus atom.

4. The polishing liquid according to claim 1, wherein the hydrocarbon group contains a butyl group.

5. The polishing liquid according to claim 1, wherein the hydrocarbon group contains a phenyl group.

6. The polishing liquid according to claim 1, wherein the quaternary phosphonium cation contains a phosphonium cation represented by general formula (I) below.
[Chemical Formula 1] 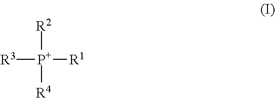
[In the formula, R¹, R², R³, and R⁴ each independently represent a hydrogen atom or a hydrocarbon group which may have a substituent, at least one of R¹, R², R³, and R⁴ is a hydrocarbon group having two or more carbon atoms which may have a substituent, and phosphorus atoms P in the formula may be bonded to each other through R¹, R², R³, or R⁴.]

7. The polishing liquid according to claim 6, wherein at least one selected from the group consisting of R¹, R², R³, and R⁴ in the general formula (I) is a hydrocarbon group substituted with at least one selected from the group consisting of a carboxyl group, a hydroxyl group, an alkoxy group, a halogeno group, an ether group, an ester group, an aldehyde group, a carbonyl group, a nitro group, a silyl group, a cyano group, an amino group, an alkylamino group, a dialkylamino group, a homocyclic group, and a heterocyclic group.

8. The polishing liquid according to claim 6, wherein two or more of R¹, R², R³, and R⁴ in the general formula (I) are an unsubstituted hydrocarbon group.

9. The polishing liquid according to claim 6, wherein R¹, R², R³, and R⁴ in the general formula (I) are an aryl group.

10. The polishing liquid according to claim 1, wherein a content of a quaternary phosphonium salt having the quaternary phosphonium cation is 0.001 to 1% by mass.

11. The polishing liquid according to claim 1, wherein a pH is less than 8.0.

12. (canceled)

13. A polishing liquid set comprising:
constituent components of the polishing liquid according to claim 1 stored while being divided into a plurality of liquids, a first liquid containing the abrasive grains, a second liquid containing the quaternary phosphonium cation.

14. A polishing method comprising a step of polishing a surface to be polished by using the polishing liquid according to claim 1.

15. The polishing method according to claim 14, wherein the surface to be polished contains polysilicon.

16. The polishing liquid according to claim 9, wherein a content of the abrasive grains is 0.5% by mass or less.

17. The polishing liquid according to claim 11, wherein a content of the abrasive grains is 0.5% by mass or less.

18. The polishing liquid according to claim 3, wherein the hydrocarbon group contains a butyl group.

19. The polishing liquid according to claim 3, wherein the hydrocarbon group contains a phenyl group.

20. The polishing liquid according to claim 3, wherein the quaternary phosphonium cation contains a phosphonium cation represented by general formula (I) below. 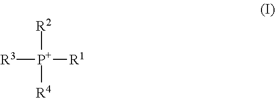
[In the formula, R¹, R², R³, and R⁴ each independently represent a hydrogen atom or a hydrocarbon group which may have a substituent, at least one of R¹, R², R³, and R⁴ is a hydrocarbon group having two or more carbon atoms which may have a substituent, and phosphorus atoms P in the formula may be bonded to each other through R¹, R², R³, or R⁴.]

21. The polishing liquid according to claim 20, wherein at least one selected from the group consisting of R¹, R², R³, and R⁴ in the general formula (I) is a hydrocarbon group substituted with at least one selected from the group consisting of a carboxyl group, a hydroxyl group, an alkoxy group, a halogeno group, an ether group, an ester group, an aldehyde group, a carbonyl group, a nitro group, a silyl group, a cyano group, an amino group, an alkylamino group, a dialkylamino group, a homocyclic group, and a heterocyclic group.

22. The polishing liquid according to claim 20, wherein two or more of R¹, R², R³, and R⁴ in the general formula (I) are an unsubstituted hydrocarbon group.

23. The polishing liquid according to claim 20, wherein R¹, R², R³, and R⁴ in the general formula (I) are an aryl group.

24. The polishing liquid according to claim 3, wherein a content of a quaternary phosphonium salt having the quaternary phosphonium cation is 0.001 to 1% by mass.

25. The polishing liquid according to claim 3, wherein a pH is less than 8.0.

26. A polishing liquid set comprising:
constituent components of the polishing liquid according to claim 3 stored while being divided into a plurality of liquids, a first liquid containing the abrasive grains, a second liquid containing the quaternary phosphonium cation.

27. A polishing method comprising a step of polishing a surface to be polished by using the polishing liquid according to claim 3.

28. The polishing method according to claim 27, wherein the surface to be polished contains polysilicon.

29. The polishing liquid according to claim 23, wherein a content of the abrasive grains is 0.5% by mass or less.

30. The polishing liquid according to claim 25, wherein a content of the abrasive grains is 0.5% by mass or less.
